(19) United States
(12) Patent Application Publication
(10) Pub. No.: US 2025/0007529 A1
(43) Pub. Date: Jan. 2, 2025

(54) SEMICONDUCTOR DEVICE, CONTROL METHOD FOR SEMICONDUCTOR DEVICE AND CONTROL PROGRAM

(71) Applicant: Renesas Electronics Corporation, Tokyo (JP)

(72) Inventors: Tetsuo MATSUI, Tokyo (JP); Atsushi TANGODA, Tokyo (JP); Keisaku SENTO, Tokyo (JP); Masaki FUJIWARA, Tokyo (JP)

(73) Assignee: Renesas Electronics Corporation, Tokyo (JP)

(21) Appl. No.: 18/753,046

(22) Filed: Jun. 25, 2024

(30) Foreign Application Priority Data
Jun. 28, 2023 (JP) 2023-105804

(51) Int. Cl. H03M 1/08

(52) U.S. Cl. CPC H03M 1/08

(57) ABSTRACT

A semiconductor device capable of operating accurately while suppressing the propagation of interference noise, a control method for the semiconductor device, and a control program are provided. The semiconductor device includes a first AD converter of a charge redistribution type sequential comparison type that includes a redundant comparison operation in a sequential comparison operation and outputs a first input signal of an analog differential using a reference voltage to a first output signal of digital, a first pin to which the reference voltage is supplied from the outside, a first variable impedance circuit provided on a signal line between the first AD converter and capable of changing impedance, and a first control circuit 10 that controls the impedance of the first variable impedance circuit according to the operating condition of the first AD converter.

### CROSS-REFERENCE TO RELATED APPLICATION

The subject application claims priority under 35 U.S.C. § 119 to Japanese Patent Application No. 2023-105804 filed on Jun. 28, 2023. The entire disclosure of Japanese Patent Application No. 2023-105804 is incorporated herein by reference.

### BACKGROUND

This disclosure relates to a semiconductor device, a control method for a semiconductor device, and a control program, for example, a semiconductor device capable of operating accurately while suppressing the propagation of interference noise, a control method for a semiconductor device, and a control program.

There are disclosed techniques listed below.

[Non-Patent Document 1] Akira Matsuzawa, “Future of Analog-ADC Development”, [online], Mar. 15, 2013, [searched on May 20, 2023], Internet <URL: http://www.ssc.pe.titech.ac.jp/publications/2013/RFanalog/matsu_open_130315.pdf>

Non-Patent Document 1 discloses a successive approximation AD converter of charge redistribution type.

### SUMMARY

In a charge redistribution type successive approximation AD converter, noise of the reference voltage occurs on the signal line where the reference voltage propagates due to the charge and discharge of the charge by switching the capacity during the successive comparison operation. In particular, in the comparison operation for determining the value of the upper bits of the digital signal, the change in current due to the charge and discharge of the charge becomes steep because a large capacity switch is performed, and the noise generated on the signal line where the reference voltage propagates becomes large. As a result, there was a problem that the noise is transmitted to other circuits that share the signal line where the reference voltage propagates, and the other circuits cannot operate accurately.

Other objects and novel features will become apparent from the description of this specification and the accompanying drawings.

A semiconductor device according to one embodiment of the present disclosure includes a first AD converter of a charge redistribution type successive approximation type that includes a redundant comparison operation in the successive comparison operation and outputs a first input signal of an analog differential using a reference voltage to a first digital output signal, a first pin to which the reference voltage is supplied from the outside, a first variable impedance circuit that is provided on a signal line between the first AD converter and is configured to be able to change the impedance, and a first control circuit that controls the impedance of the first variable impedance circuit according to the operating condition of the first AD converter.

The control method of the semiconductor device according to one embodiment of the present disclosure is a control method of a semiconductor device that includes a first AD converter of a charge redistribution type successive approximation type that includes a redundant comparison operation in the successive comparison operation and outputs a first input signal of an analog differential using a reference voltage to a first digital output signal, a first pin to which the reference voltage is supplied from the outside, a first variable impedance circuit that is provided on a signal line between the first AD converter and is configured to be able to change the impedance, and a first control circuit that controls the impedance of the first variable impedance circuit according to the operating condition of the first AD converter, and controls the impedance of the first variable impedance circuit to a first impedance, performs a comparison operation to determine the value of the upper bits of a first predetermined range of multiple bits representing the first output signal in the first AD converter, controls the impedance of the first variable impedance circuit to a second impedance lower than the first impedance, and performs a comparison operation to determine the value of the lower bits other than the upper bits of the first predetermined range of multiple bits representing the first output signal in the first AD converter, and a redundant comparison operation.

The control program according to one embodiment of the present disclosure includes a redundant comparison operation in a sequential comparison operation, and outputs a first analog differential input signal into a first digital output signal using a reference voltage, a charge redistribution type sequential comparison type first AD converter, a first pin to which the reference voltage is supplied from the outside, a first variable impedance circuit that is provided on a signal line between the first AD converter and is capable of changing impedance, and a first control circuit that controls the impedance of the first variable impedance circuit according to the operating condition of the first AD converter, and is a control program that causes a computer to execute control processing in a semiconductor device, and controls the impedance of the first variable impedance circuit to a first impedance, and executes a comparison operation to determine the value of the upper bits in a first predetermined range of multiple bits representing the first output signal in the first AD converter, and controls the impedance of the first variable impedance circuit to a second impedance lower than the first impedance, and in the first AD converter, a comparison operation to determine the value of the lower bits other than the upper bits in the first predetermined range of multiple bits representing the first output signal, and a redundant comparison operation, to be executed by a computer.

The present disclosure can provide a semiconductor device that can operate accurately while suppressing the propagation of interference noise, a control method for a semiconductor device, and a control program.

### BRIEF DESCRIPTION OF THE DRAWINGS

FIG. 1 is a block diagram showing a configuration example of a semiconductor device according to the first embodiment.

FIG. 2 is a diagram showing the AD converter of the semiconductor device shown in FIG. 1 in more detail.

FIG. 3 is a diagram showing an exemplary example of a semiconductor device according to the first embodiment.

FIG. 4 is a diagram for explaining interference noise generated in the semiconductor device shown in FIG. 3.

FIG. 5 is a timing chart showing the operation of the semiconductor device shown in FIG. 3.

FIG. 6 is a waveform diagram for explaining interference noise generated in the semiconductor device shown in FIG. 3.

FIG. 7 is a diagram for explaining the sequential comparison operation of each AD converter provided in the semiconductor device shown in FIG. 3.

FIG. 8 is a block diagram showing a configuration example of a semiconductor device according to the second embodiment.

FIG. 9 is a diagram showing an exemplary example of a semiconductor device according to the second embodiment.

FIG. 10 is a block diagram showing a configuration example of a semiconductor device according to the third embodiment.

FIG. 11 is a timing chart showing the operation of the semiconductor device shown in FIG. 10.

FIG. 12 is a block diagram showing another configuration example of a semiconductor device according to the third embodiment.

FIG. 13 is a diagram showing a first configuration example of a pre-examined semiconductor device.

FIG. 14 is a diagram for explaining the propagation path of interference noise generated in the semiconductor device shown in FIG. 13.

FIG. 15 is a timing chart showing the operation of each AD converter provided in the semiconductor device shown in FIG. 13.

FIG. 16 is a waveform diagram for explaining noise generated in the semiconductor device shown in FIG. 13.

FIG. 17 is a diagram showing a second configuration example of a pre-examined semiconductor device.

FIG. 18 is a diagram for explaining the propagation path of interference noise generated in the semiconductor device shown in FIG. 17.

FIG. 19 is a waveform diagram for explaining noise generated in the semiconductor device shown in FIG. 17.

FIG. 20 is a diagram showing a third configuration example of a pre-examined semiconductor device.

FIG. 21 is a diagram for explaining the propagation path of interference noise generated in the semiconductor device shown in FIG. 20.

FIG. 22 is a waveform diagram for explaining noise generated in the semiconductor device shown in FIG. 20.

FIG. 23 is a diagram for explaining the ideal sequential comparison operation of the AD converter provided in the semiconductor device shown in FIG. 20.

FIG. 24 is a diagram for explaining the problems that occur in the sequential comparison operation of the AD converter provided in the semiconductor device shown in FIG. 20.

FIG. 25 is a diagram showing a fourth configuration example of a pre-examined semiconductor device.

FIG. 26 is a diagram for explaining the ideal sequential comparison operation of the AD converter provided in the semiconductor device shown in FIG. 25.

FIG. 27 is a diagram for explaining the problems that occur in the sequential comparison operation of the AD converter provided in the semiconductor device shown in FIG. 25.

### DETAILED DESCRIPTION

Hereinafter, the embodiments will be described with reference to the drawings. The drawings are simplified, and therefore, the technical scope of the embodiments should not be narrowly interpreted based on the descriptions in the drawings. The same reference numerals are assigned to the same elements, and redundant descriptions are omitted.

For convenience, the following embodiments may be divided into multiple sections or embodiments when necessary. However, unless specifically stated, they are not unrelated to each other, and one may be a part or all of a modified example, application example, detailed description, supplementary description, etc. of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle.

Furthermore, in the following embodiments, the constituent elements (including the operation steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above-mentioned numbers and the like, including the number, the numerical value, the amount, the range, and the like.

### <Preliminary Study by Inventors>

Before describing the semiconductor device according to the present embodiment, a semiconductor device that the inventors, etc. have preliminarily studied will be described.

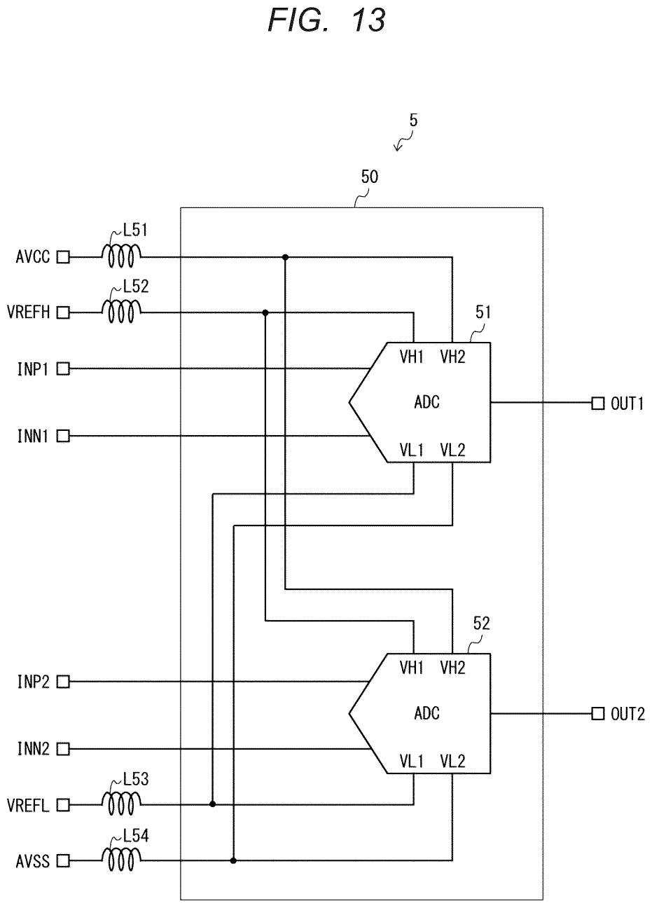

FIG. 13 is a diagram showing a configuration example of the preliminarily studied semiconductor device 5. The semiconductor device 5 is, for example, an MCU (Micro Controller Unit) equipped with multiple AD converters. In the example of FIG. 13, the semiconductor device S is equipped with two AD converters 51, 52 on the chip 50. The semiconductor device 5 is also provided with multiple pins that serve as an interface between the chip 50 and the outside of the semiconductor device 5.

The pin AVCC is supplied with a common high-potential-side power supply voltage (hereinafter referred to as power supply voltage AVCC) for the AD converters 51, 52 from the outside of the semiconductor device 5. The pin AVSS is supplied with a common low-potential-side power supply voltage (hereinafter referred to as power supply voltage AVSS) for the AD converters 51, 52 from the outside of the semiconductor device 5. In other words, the AD converters 51, 52 share the pins AVCC, AVSS.

The pin VREFH is supplied with a common high-potential-side reference voltage (hereinafter referred to as reference voltage VREFH) for the AD converters 51, 52 from the outside of the semiconductor device 5. The pin AVSS is supplied with a common low-potential-side reference voltage (hereinafter referred to as reference voltage VREFL) for the AD converters 51, 52 from the outside of the semiconductor device 5. In other words, the AD converters 51, 52 share the pins VREFH, VREFL.

Here, a parasitic inductor L51 is formed on the signal line connected to the pin AVCC by a board substrate, a lead frame, a bonding wire, etc. (all not shown). Similarly, a parasitic inductor L52 is formed on the signal line connected to the pin VREFH. A parasitic inductor L53 is formed on the signal line connected to the pin VREFL. A parasitic inductor L54 is formed on the signal line connected to the pin AVSS.

One and the other of the differential input signal IN1, which is analog and is AD. converted by the AD converter 51, are supplied from the outside of the semiconductor device 5 to the pins INP1, INN1, respectively. One and the other of the differential input signal IN2, which is analog and is AD-converted by the AD converter 52, are supplied from the outside of the semiconductor device 5 to the pins INP2, INN2, respectively.

At pin OUT1, a digital output signal (hereinafter referred to as output signal OUT1), which is the result of AD conversion by AD converter 51, is output to the outside of the semiconductor device 5. At pin OUT2, a digital output signal (hereinafter referred to as output signal OUT2), which is the AD conversion result by AD converter 52, is output to the outside of the semiconductor device 5.

The AD converter 51 is a charge redistribution type successive approximation AD converter, which uses a binary search algorithm to convert an analog differential input signal IN1 into a digital output signal OUT1 and outputs it. The AD converter 51 is configured to perform AD conversion based on the difference of reference voltages VREFH and VREFL for the differential input signal IN1, so it can improve the power supply voltage AVCC, AVSS fluctuation removal ratio.

The AD converter 51 performs a successive comparison operation for the input signal IN1 while redistributing the charges stored in each of the multiple capacitive elements based on the potential of the input signal IN1 and the reference voltages VREFH and VREFL, by switching the connection of the multiple capacitive elements by multiple switches.

Among the multiple terminals provided in the AD converter 51, the reference voltage VREFH is supplied to the terminal VH1. The power supply voltage AVCC is supplied to the terminal VH2. The reference voltage VREFL is supplied to the terminal VL1. The power supply voltage AVSS is supplied to the terminal VL2. The power supply voltages AVCC, AVSS are used to drive the AD converter 51, and the reference voltages VREFH, VREFL are used in the successive comparison operation of the AD converter 51.

The AD converter 52, like the AD converter 51, is a charge redistribution type successive approximation AD converter, which uses a binary search algorithm to convert an analog differential input signal IN2 into a digital output signal OUT2 and outputs it. The AD converter 52 is configured to perform AD conversion based on the difference of reference voltages VREFH and VREFL for the differential input signal IN2, so it can improve the power supply voltage AVCC, AVSS fluctuation removal ratio.

The AD converter 52 performs a successive comparison operation for the input signal IN2 while redistributing the charges stored in each of the multiple capacitive elements based on the potential of the input signal IN2 and the reference voltages VREFH and VREFL, by switching the connection of the multiple capacitive elements by multiple switches.

Among the multiple terminals provided in the AD converter 52, the reference voltage VREFH is supplied to the terminal VH1. The power supply voltage AVCC is supplied to the terminal VH2. The reference voltage VREFL is supplied to the terminal VL1. The power supply voltage AVSS is supplied to the terminal VL2. The power supply voltages AVCC, AVSS are used to drive the AD converter 52, and the reference voltages VREFH. VREFL are used in the successive comparison operation of the AD converter 52.

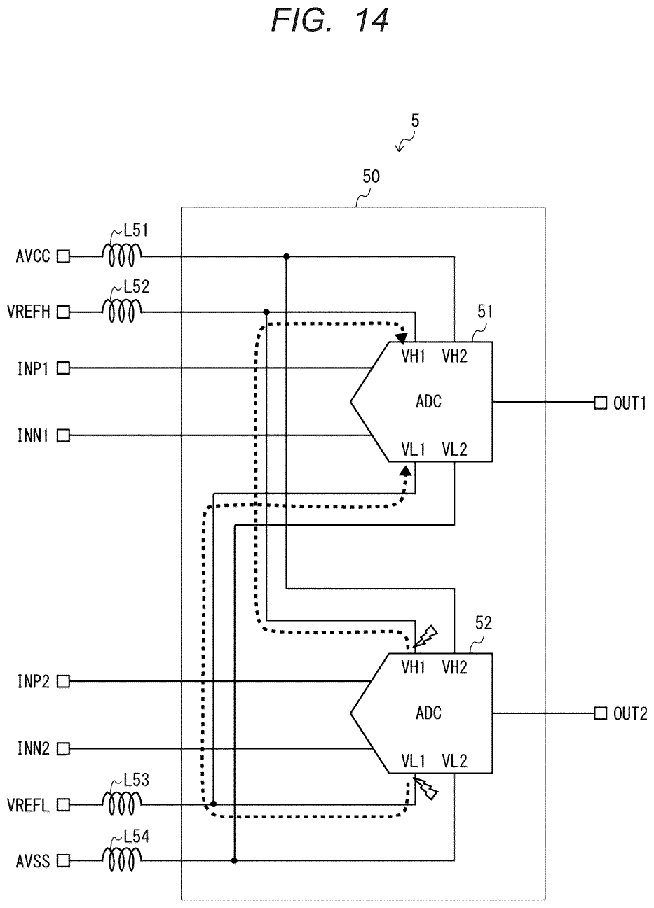

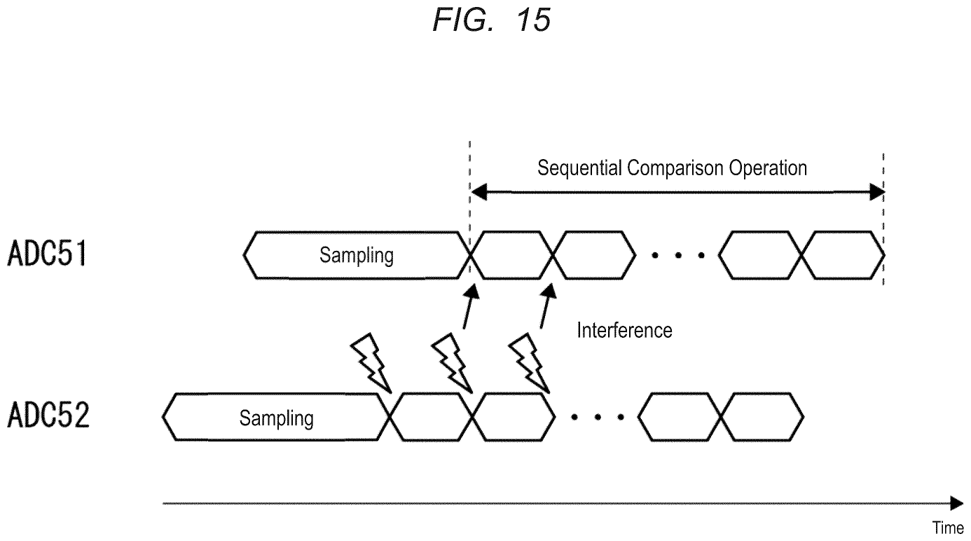

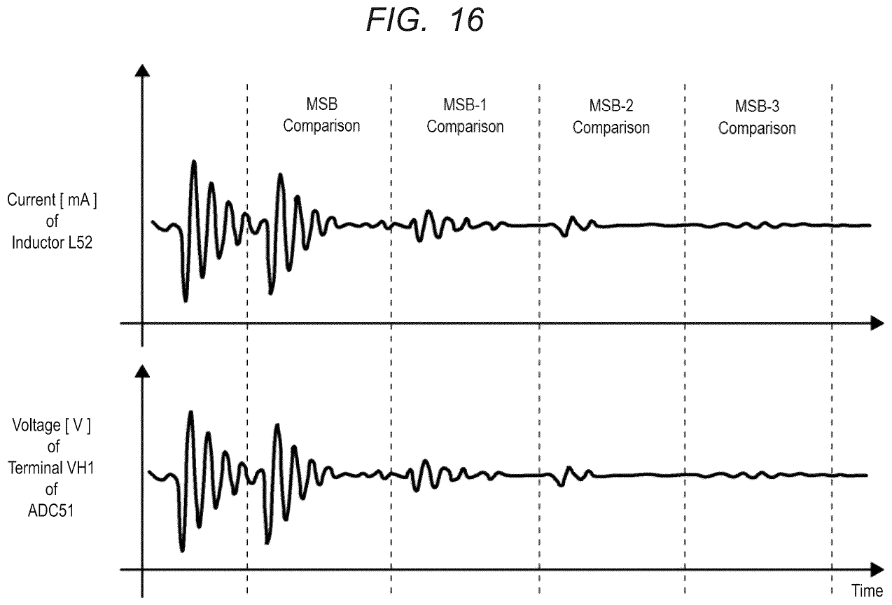

FIG. 14 is a diagram for explaining the propagation path of interference noise generated in the semiconductor device 5. FIG. 15 is a timing chart showing the operation of each AD converter provided in the semiconductor device 5. FIG. 16 is a waveform diagram for explaining the noise generated in the semiconductor device 5.

Generally, it is known that in inductors such as parasitic inductors L51 to L54. the impedance changes greatly due to sudden changes in current.

Here, for example, in the AD converter 52, assume that the capacity switching of the successive comparison operation is performed asynchronously with the AD converter 51 (see FIG. 15). At this time, at the terminals VH1, VL1 of the AD converter 52 (terminals where the reference voltages VREFH, VREFL are supplied), the current changes due to the charge discharge caused by the capacity switching. Especially in the comparison operation to determine the value of the upper bit of the digital output signal OUT2, the change in current due to the charge discharge becomes steep because a large capacity switching is performed. When this steep change in current at the terminals VH1, VL1 of the AD converter 52 is transmitted to the parasitic inductors L52, L53, the impedance of the parasitic inductors L52, L53 changes greatly (see FIG. 16). As a result, the reference voltages VREFH, VREFL supplied to the terminals VH1, VL1 of the AD converter 51 also change greatly (see FIG. 16). In other words, the noise generated at the terminals VH1, VL1 of the aggressor AD converter 52 is transmitted to the terminals VH1, VL1 of the victim AD converter 51. As a result, the AD converter 51 may no longer be able to operate accurately.

Therefore, the inventors have considered the semiconductor device 6 next.

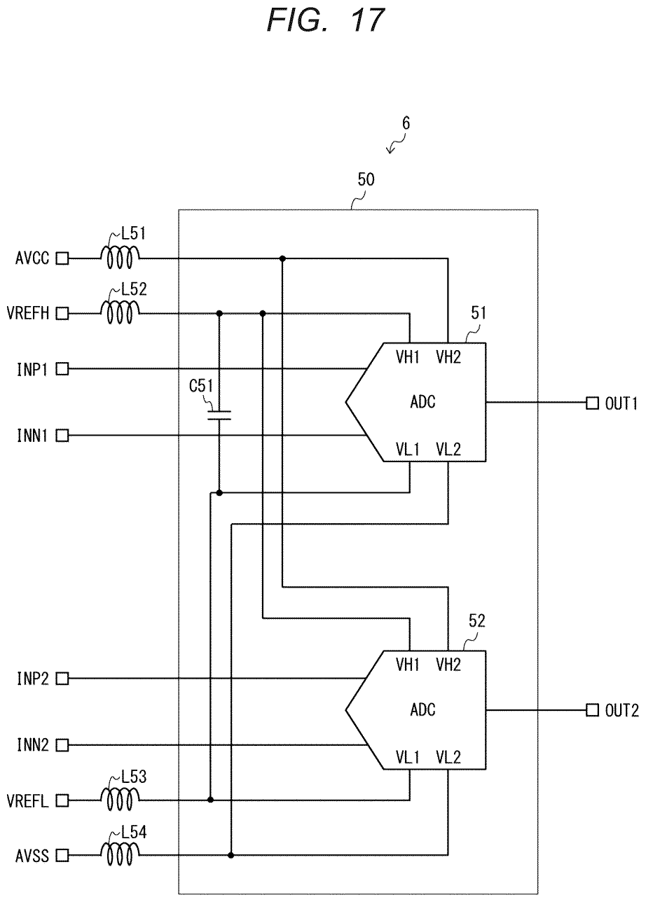

FIG. 17 is a diagram showing a configuration example of the semiconductor device 6 that was pre-examined. The semiconductor device 6 further includes a bypass capacitor C51 on the chip 50 as compared to the semiconductor device 5. The bypass capacitor C51 is provided between a common signal line for the AD converters 51, 52 through which the reference voltage VREFH propagates, and a common signal line for the AD converters 51, 52 through which the reference voltage VREFL propagates, within the chip 50. The capacitance value of the bypass capacitor C51 is, for example, about 100 pF to 1 nF. The other configurations of the semiconductor device 6 are the same as those of the semiconductor device 5, and therefore, their description is omitted.

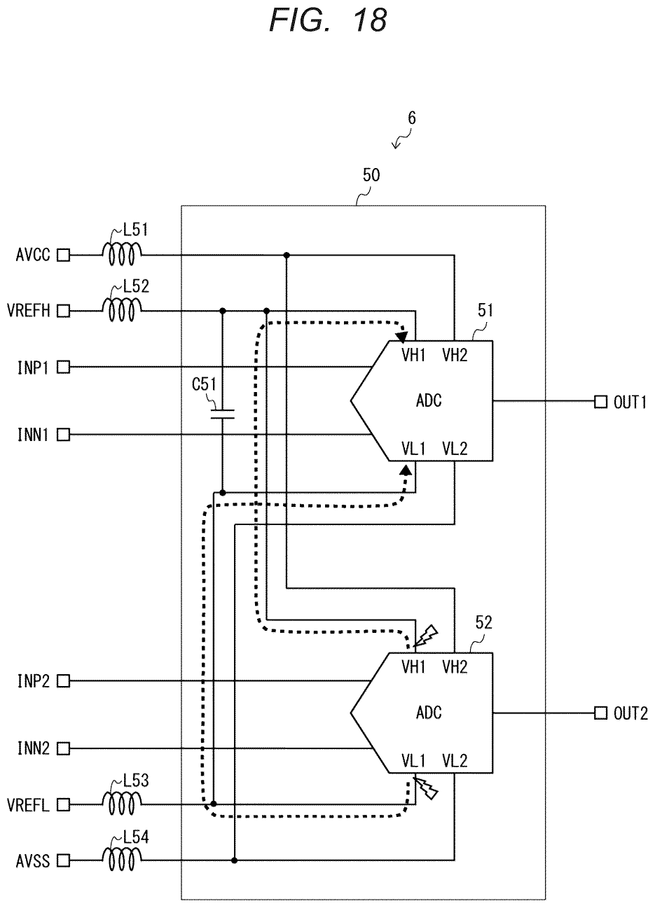

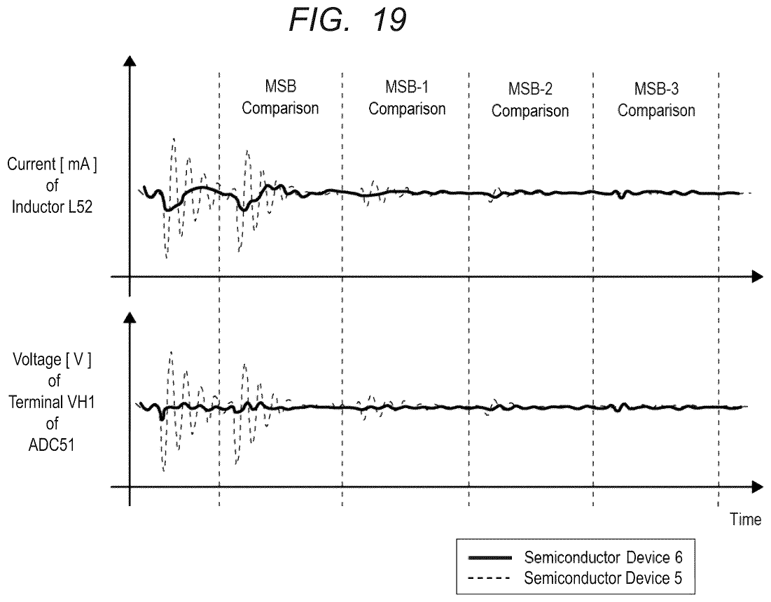

FIG. 18 is a diagram for explaining the propagation path of interference noise generated in the semiconductor device 6. FIG. 19 is a waveform diagram for explaining the noise generated in the semiconductor device 6.

In the semiconductor device 6, as in the case of the semiconductor device 5, the current changes abruptly at the terminals VH1, VL1 of the AD converter 52 due to the charge and discharge of the capacity by the sequential comparison operation. However, in the semiconductor device 6, the change in the current flowing through each of the parasitic inductors L52, L53 is suppressed by the bypass capacitor C51, so the change in the impedance of each of the parasitic inductors L52, L53 becomes small (see FIG. 19). As a result, the fluctuations in the reference voltages VREFH, VREFL supplied to each of the terminals VH1, VL1 of the AD converter 51 are suppressed (see FIG. 19). In other words, the propagation of the noise generated at each of the terminals VH1, VL1 of the AD converter 52, which is an aggressor, to the terminals VH1, VL1 of the AD converter 51, which is a victim, is suppressed. As a result, the AD converter 51 can operate accurately.

However, in the semiconductor device 6, the chip size increases because the scale of the bypass capacitor C51 is large.

Therefore, the inventors have considered the semiconductor device 7 next.

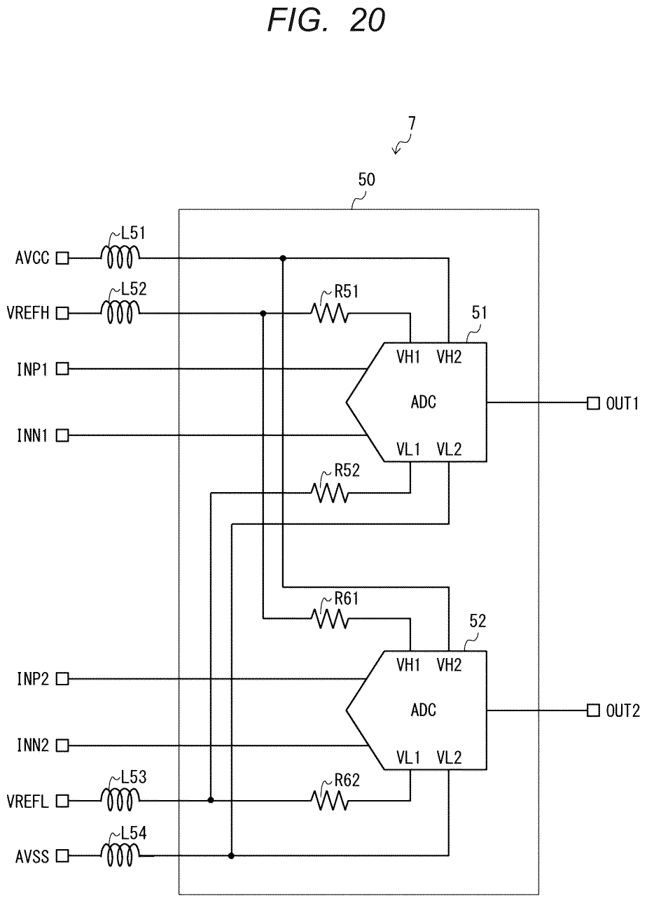

FIG. 20 is a diagram showing a configuration example of the semiconductor device 7 that was pre-examined. The semiconductor device 7 includes, on the chip 50, resistive elements R51, R52, R61, R62, which are smaller in scale than the bypass capacitor C51, instead of the bypass capacitor C51, compared to the semiconductor device 6.

The resistive element R51 is provided on a signal line branching from a signal line common to the AD converter 52, among the signal lines between the pin VREFH and the terminal VH1 of the AD converter 51. The resistive element R52 is provided on a signal line branching from a signal line common to the AD converter 52, among the signal lines between the pin VREFL and the terminal VL1 of the AD converter 51. The resistive element R61 is provided on a signal line branching from a signal line common to the AD converter 51, among the signal lines between the pin VREFH and the terminal VH1 of the AD converter 52. The resistive element R62 is provided on a signal line branching from a signal line common to the AD converter 51, among the signal lines between the pin VREFL and the terminal VL1 of the AD converter 52. The other configurations of the semiconductor device 7 are the same as those of the semiconductor device 6, and therefore, their description is omitted. As a result, the semiconductor device 7 can suppress the increase in circuit scale compared to the semiconductor device 6.

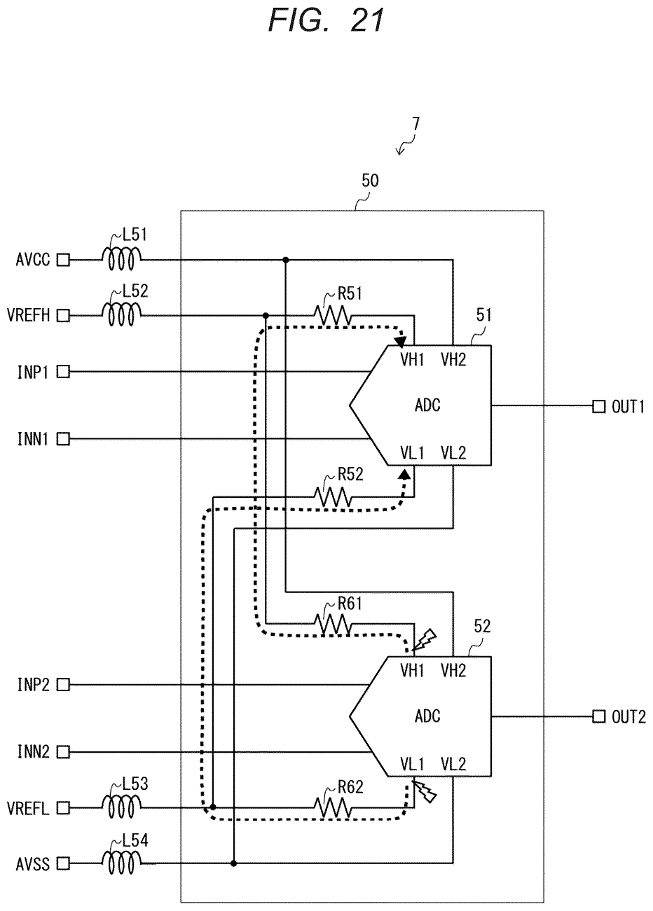

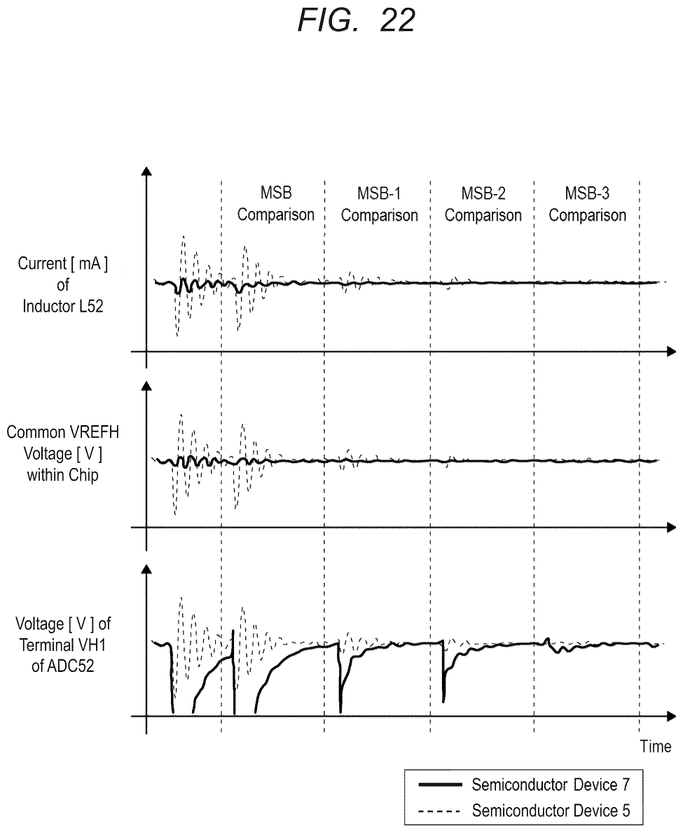

FIG. 21 is a diagram for explaining the propagation path of interference noise generated in the semiconductor device 7. FIG. 22 is a waveform diagram for explaining the noise generated in the semiconductor device 7.

In the semiconductor device 7, as in the case of the semiconductor device 5, the current changes abruptly at the terminals VH1, VL1 of the AD converter 52 due to the charge and discharge of the capacity by the sequential comparison operation. However, in the semiconductor device 7, the changes in the current flowing through each of the parasitic inductors L52, L53 due to the resistive elements R51, R52, R61, R62 are suppressed, thereby reducing the changes in the impedance of each of the parasitic inductors L52, L53 (refer to FIG. 22). As a result, the fluctuations in the reference voltages VREFH, VREFL supplied to each of the terminals VH1, VL1 of the AD converter 51 are suppressed (refer to FIG. 22). In other words, the propagation of noise generated at each of the terminals VH1, VL1 of the AD converter 52, which is the aggressor, to the terminals VH1, VL1 of the AD converter 51, which is the victim, is suppressed. However, due to the IR drop caused by the resistive elements R61, R62, the reference voltages VREFH, VREFL supplied to each of the terminals VH1, VL1 of the AD converter 52, which is the aggressor, fluctuate significantly (refer to FIG. 22). As a result, the AD converter 52 cannot operate accurately.

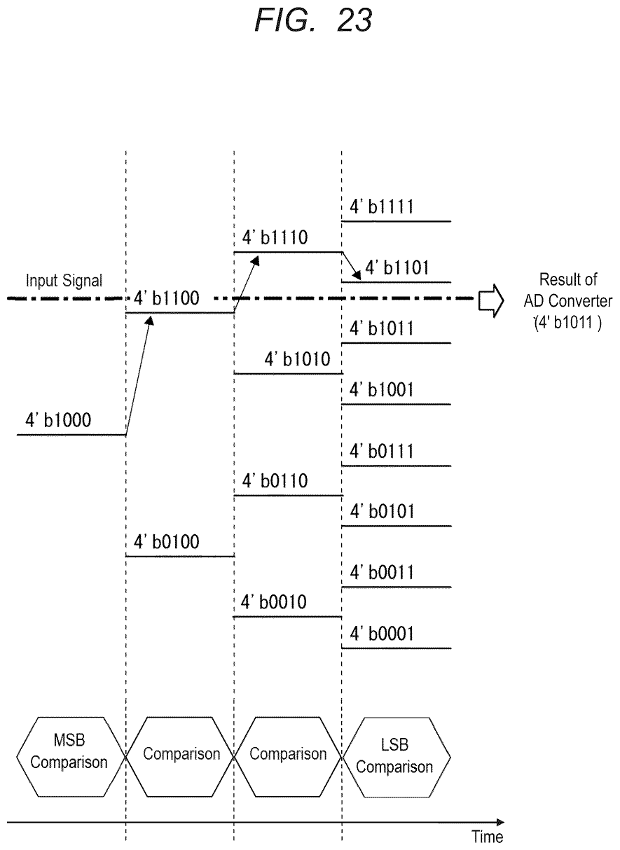

FIG. 23 is a diagram for explaining the ideal successive comparison operation of the AD converter provided in the semiconductor device 7. In the example of FIG. 23, the AD converter 52 converts the analog input signal IN2 into a 4-bit wide digital output signal OUT2 and outputs it.

First, the AD converter 52 samples the input signal IN2 and holds the sampled input signal IN2.

Next, the AD converter 52 performs a successive comparison operation for the input signal IN2 while redistributing the charges accumulated in each of the multiple capacitive elements based on the potential of the input signal IN2 and the reference voltages VREFH, VREFL (hereinafter, collectively referred to as the reference voltage VREF) by switching the connection of the multiple capacitive elements with multiple switches.

First, the AD converter 52 performs a comparison operation to determine the value of the most significant bit (MSB) of the 4 bits representing the output signal OUT2. For example, the AD converter 52 compares the potential of the sampled input signal IN2 with the DA conversion value of the digital value 4b′1000 set to “1” for the most significant bit. If the potential of the input signal IN2 is equal to or greater than the DA conversion value of the digital value 4b′1000, the most significant bit of the output signal OUT2 is determined to be “1”, and if the potential of the input signal IN2 is less than the DA conversion value of the digital value 4b′1000, the most significant bit of the output signal OUT2 is determined to be “0”. In the example of FIG. 23, since the potential of the input signal IN2 is equal to or greater than the DA conversion value of the digital value 4b′1000, the most significant bit of the output signal OUT2 is determined to be “1”.

Subsequently, the AD converter 52 performs a comparison operation to determine the value of the second highest bit (the second bit from the top) of the output signal OUT2 by switching the connection of the capacitive elements with a switch and redistributing the charges.

For example, the AD converter 52 compares the potential of the sampled input signal IN2 with the DA conversion value of the digital value 4b′1100 set to “1” for the second highest bit. If the potential of the input signal IN2 is equal to or greater than the DA conversion value of the digital value 4b′1100, the second highest bit of the output signal OUT2 is determined to be “1” and if the potential of the input signal IN2 is less than the DA conversion value of the digital value 4b′1100, the second highest bit of the output signal OUT2 is determined to be “0”. In the example of FIG. 23, since the potential of the input signal IN2 is equal to or greater than the DA conversion value of the digital value 4b′1100. the second highest bit of the output signal OUT2 is determined to be “1”.

Subsequently, the AD converter 52 performs a comparison operation to determine the value of the third highest bit (the third bit from the top) of the output signal OUT2 by switching the connection of the capacitive elements with a switch and redistributing the charges. For example, the AD converter 52 compares the potential of the sampled input signal IN2 with the DA conversion value of the digital value 4b′1110, where the upper third bit is set to “1”. If the potential of the input signal IN2 is equal to or greater than the DA conversion value of the digital value 4b′1110, the upper third bit of the output signal OUT2 is confirmed as “1”. If the potential of the input signal IN2 is less than the DA conversion value of the digital value 4b′1110, the upper third bit of the output signal OUT2 is confirmed as “0”. In the example of

FIG. 23, the upper third bit of the output signal OUT2 is confirmed as “0” because the potential of the input signal IN2 is less than the DA conversion value of the digital value 4b′1110.

Subsequently, the AD converter 52 performs a comparison operation to determine the value of the upper fourth bit (the least significant bit) of the output signal OUT2 by switching the connection of the capacitive element and redistributing the charge. For example, the AD converter 52 compares the potential of the sampled input signal IN2 with the DA conversion value of the digital value 4b′1101, where the least significant bit is set to “1”. If the potential of the input signal IN2 is equal to or greater than the DA conversion value of the digital value 4b′1101, the least significant bit of the output signal OUT2 is confirmed as “1”. If the potential of the input signal IN2 is less than the DA conversion value of the digital value 4b′1101, the least significant bit of the output signal OUT2 is confirmed as “0”. In the example of FIG. 23, the least significant bit of the output signal OUT2 is confirmed as “0” because the potential of the input signal IN2 is less than the DA conversion value of the digital value 4b′1101.

As a result, the AD converter 52 ideally converts the analog input signal IN2 into AD and outputs the output signal OUT2 of the digital value 4b′1100.

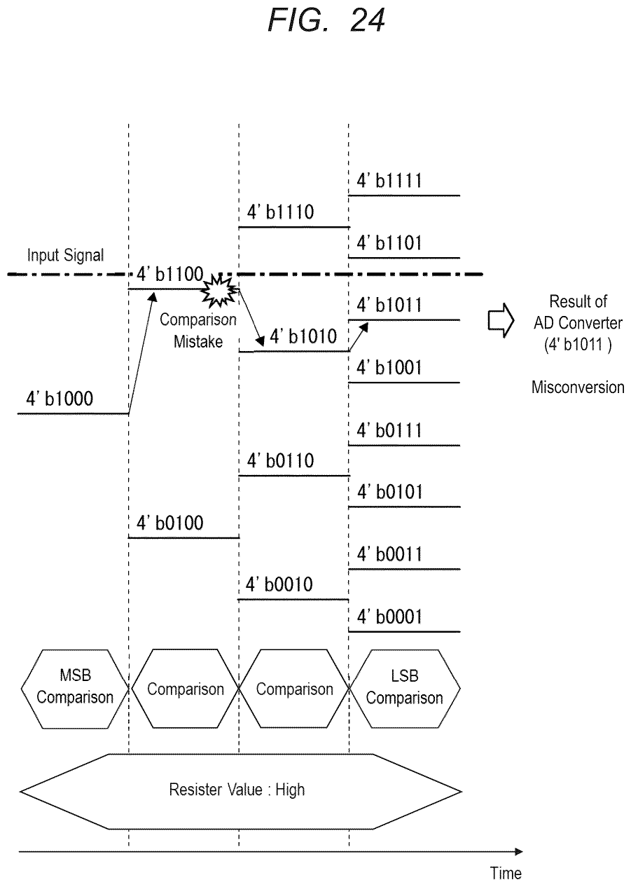

FIG. 24 is a diagram for explaining a problem that occurs in the sequential comparison operation of the AD converter provided in the semiconductor device 7. In the example of FIG. 24, the AD converter 52 converts the analog input signal IN2 into a digital output signal OUT2 with a width of 4 bits and outputs it.

As shown in FIG. 24, after confirming the most significant bit of the output signal OUT2, the AD converter 52 performs a comparison operation to determine the value of the upper second bit of the output signal OUT2 by switching the connection of the capacitive element and redistributing the charge. Here, the reference voltages VREFH and VREFL supplied to the AD converter 52 fluctuate greatly due to the IR drop caused by the resistive elements R61 and R62 accompanying the switching of the connection of the capacitive element. As a result, the AD converter 52 may make a comparison mistake due to the setting error. In the example of FIG. 24, the potential of the input signal IN2 is judged to be less than the DA conversion value of the digital value 4b′1100, despite the potential of the input signal IN2 being equal to or greater than the DA conversion value of the digital value 4b′1100. Therefore, the upper second bit of the output signal OUT2 is erroneously confirmed as “0”.

As a result, the AD converter 52 erroneously converts the analog input signal IN2 into AD and outputs the output signal OUT2 of the digital value 4b′1011.

Therefore, the inventors have considered the semiconductor device 8 next.

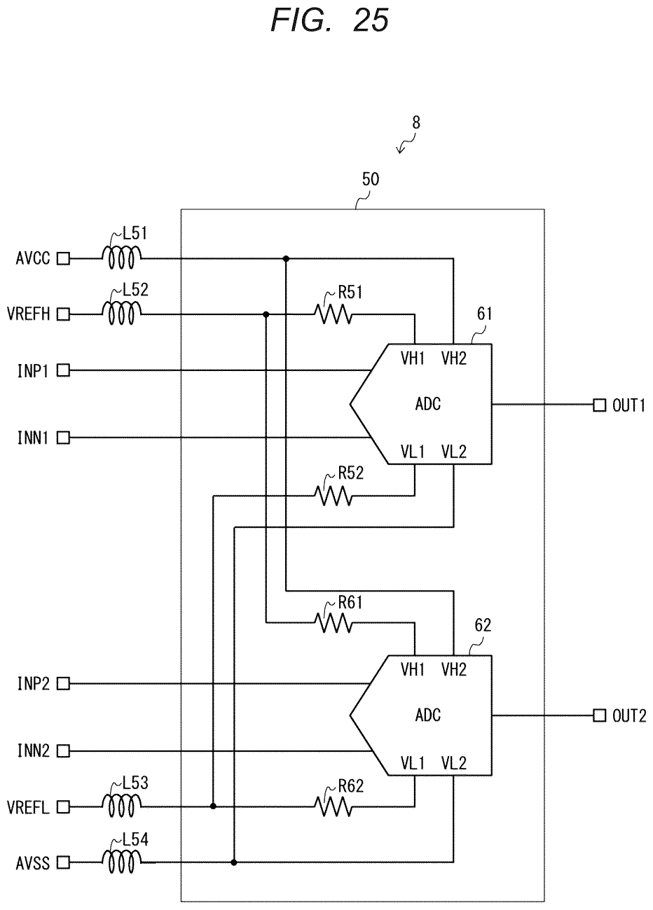

FIG. 25 is a diagram showing a configuration example of the semiconductor device 8 that has been preliminarily considered. The semiconductor device 8 is equipped with AD converters 61 and 62 instead of AD converters 51 and 52 as compared with the semiconductor device 7. Each of the AD converters 61 and 62 is configured to further include a redundant comparison operation in the sequential comparison operation. As a result, even if each of the AD converters 61 and 62 makes a comparison mistake due to the fluctuation of the reference voltages VREFH and VREFL caused by the IR drop of the resistive elements R51. R52, R61, and R62, the comparison mistake can be recovered by the redundant comparison.

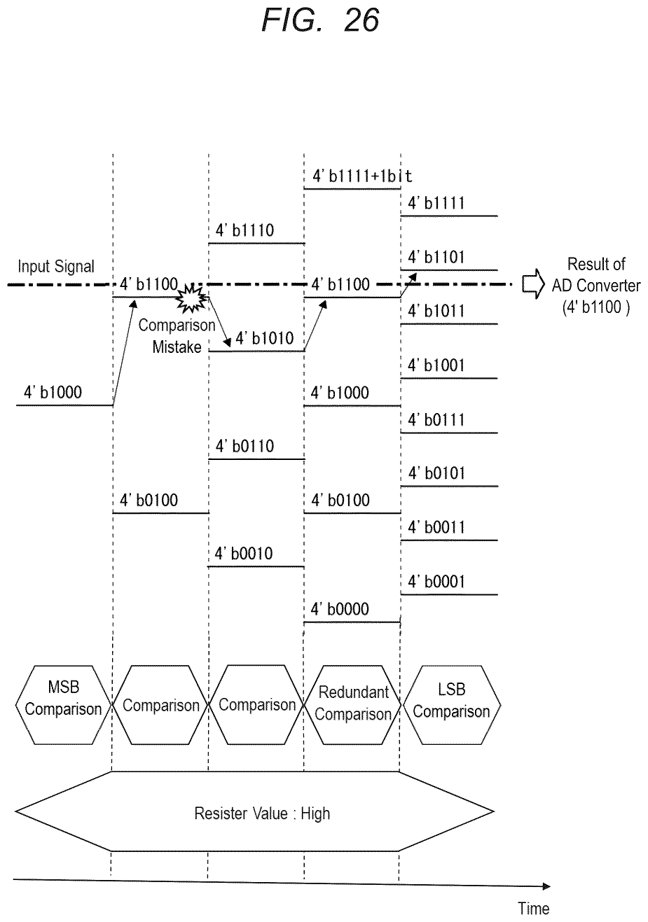

FIG. 26 is a diagram for explaining an ideal sequential comparison operation of the AD converter provided in the semiconductor device 8. In the example of FIG. 26, the AD converter 62 converts the analog input signal IN2 into a digital output signal OUT2 with a width of 4 bits and outputs it.

As shown in FIG. 26, after confirming the most significant bit of the output signal OUT2, the AD converter 62 performs a comparison operation to determine the value of the upper second bit of the output signal OUT2 by switching the connection of the capacitive element and redistributing the charge. Here, the reference voltages VREFH and VREFL supplied to the AD converter 52 fluctuate significantly due to the IR drop caused by the resistors R61 and R62 accompanying the switching of the connection of the capacitive element. As a result, the AD converter 62 may make a comparison error due to the setting error. In the example of FIG. 26, despite the potential of the input signal IN2 being equal to or greater than the DA conversion value of the digital value 4b′1100, the potential of the input signal IN2 is determined to be less than the DA conversion value of the digital value 4b′1100. Therefore, the second highest bit of the output signal OUT2 is erroneously determined to be “0”.

Here, the AD converter 62 performs a redundant comparison operation with the same resolution as the comparison operation for determining the value of the third highest bit of the output signal OUT2, by switching the connection of the capacitive element by a switch and redistributing the charge after the comparison operation for determining the value of the third highest bit of the output signal OUT2.

For example, in the comparison operation for determining the value of the third highest bit of the output signal OUT2, the AD converter 62, when the potential of the input signal IN2 is determined to be equal to or greater than the DA conversion value of the comparison target digital value, performs a comparison in the next redundant comparison operation between the potential of the input signal IN2 and the DA conversion value of the digital value obtained by adding 4′b0010 to the comparison target digital value. Also, in the comparison operation for determining the value of the third highest bit of the output signal OUT2, the AD converter 62.

when the potential of the input signal IN2 is determined to be less than the DA conversion value of the comparison target digital value, performs a comparison in the next redundant comparison operation between the potential of the input signal IN2 and the DA conversion value of the digital value obtained by subtracting 4′b0010 from the comparison target digital value.

In the example of FIG. 26, the AD converter 62, in the comparison operation for determining the value of the third highest bit of the output signal OUT2, has determined that the potential of the input signal IN2 is equal to or greater than the DA conversion value of the digital value 4′b1010, so in the next redundant comparison operation, it compares the potential of the input signal IN2 with the digital value 4′b1100 obtained by adding 4′b0010 to the digital value 4′b1010.

Then, in the example of FIG. 26, the potential of the input signal IN2 is determined to be equal to or greater than the DA conversion value of the digital value 4′b1100. Therefore, the AD converter 62, in the comparison operation for determining the value of the lowest bit, compares the potential of the input signal IN2 with the DA conversion value of the digital value obtained by adding 4′b0001 to the comparison target digital value. For example, the AD converter 62, in the comparison operation for determining the value of the lowest bit, compares the potential of the input signal IN2 with the digital value 4′b1101 obtained by adding 4′b0001 to the digital value 4′b1100. The comparison operation for determining the value of the lowest bit by the AD converter 62 is the same as in the case of the AD converter 52.

Note that, if the potential of the input signal IN2 is determined to be less than the DA conversion value of the digital value 4′b1100, the AD converter 62 compares the potential of the input signal IN2 with the DA conversion value of the digital value obtained by subtracting 4′b00001 from the comparison target digital value.

In this way, ideally, the AD converter 62 can recover from a comparison error caused by the fluctuation of the reference voltages VREFH and VREFL due to the IR drop of the resistors R61 and R62 by redundant comparison. The same applies to the AD converter 61.

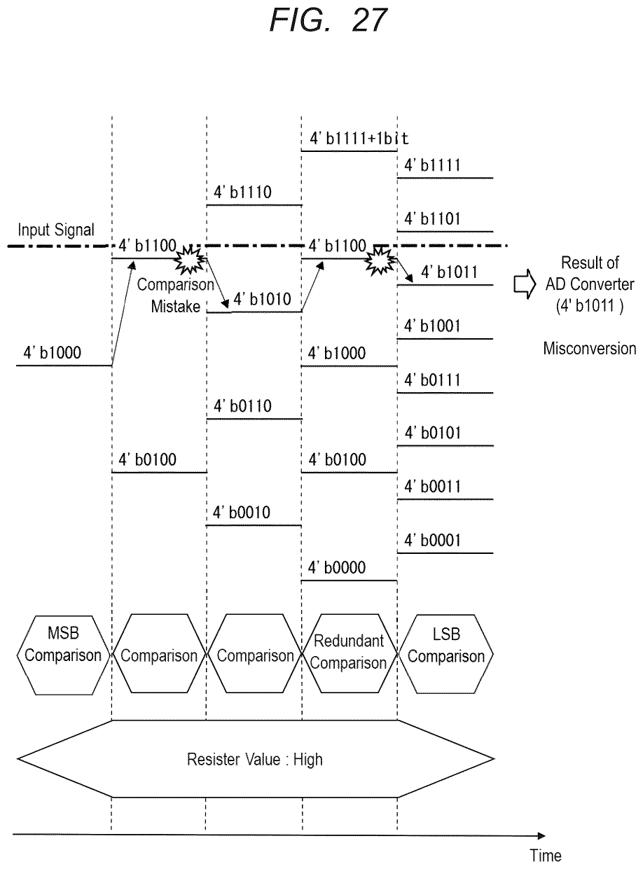

However, in reality, the AD converter 62 is likely to make a comparison error due to the fluctuation of the reference voltages VREFH and VREFL caused by the IR drop of the resistors R61 and R62, even in the redundant comparison operation (see FIG. 27).

Therefore, a semiconductor device 1 capable of operating accurately while suppressing the propagation of interference noise has been found.

### <First Embodiment>

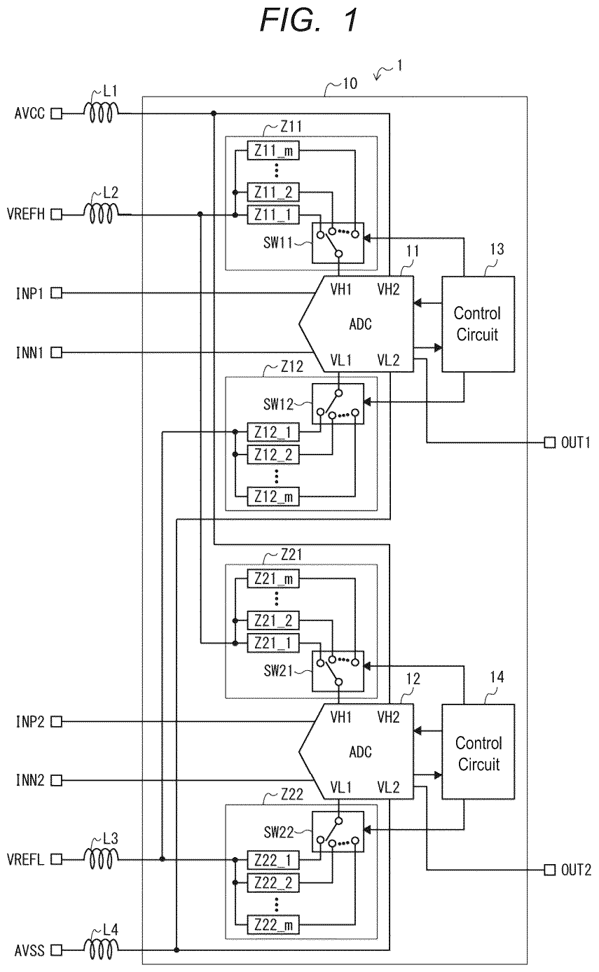

FIG. 1 is a block diagram showing a configuration example of a semiconductor device 1 according to the first embodiment. The semiconductor device 1 is, for example, an MCU equipped with multiple AD converters. In the present embodiment, the semiconductor device 1 is described as an example where it is equipped with two AD converters 11 and 12 on the chip

For example, the semiconductor device 1 includes AD converters 11, 12, control circuits 13, 14, variable impedance circuits Z11, Z12, and variable impedance circuits Z21, Z22, on the chip 10. Furthermore, the semiconductor device I is provided with a plurality of pins that perform an interface between the chip 10 and the outside of the semiconductor device 1.

The pin AVCC is supplied with a common high-potential side power supply voltage (hereinafter referred to as power supply voltage AVCC) for the AD converters 11, 12 from the outside of the semiconductor device 1. The pin AVSS is supplied with a common low-potential side power supply voltage (hereinafter referred to as power supply voltage AVSS) for the AD converters 11, 12 from the outside of the semiconductor device 1. In other words, the AD converters 11. 12 share the pins AVCC, AVSS.

The pin VREFH is supplied with a common high-potential side reference voltage (hereinafter referred to as reference voltage VREFH) for the AD converters 11, 12 from the outside of the semiconductor device 1. The pin VREFL is supplied with a common low-potential side reference voltage (hereinafter referred to as reference voltage VREFL) for the AD converters 11, 12 from the outside of the semiconductor device 1. In other words, the AD converters 11, 12 share the pins VREFH, VREFL.

On the signal line connected to the pin AVCC, a parasitic inductor L1 is formed by a board substrate, a lead frame, a bonding wire, etc. (all not shown). Similarly, a parasitic inductor L2 is formed on the signal line connected to the pin VREFH. A parasitic inductor L3 is formed on the signal line connected to the pin VREFL. A parasitic inductor L4 is formed on the signal line connected to the pin AVSS.

The pins INP1, INN1 are supplied with one and the other of the analog differential input signal IN1, which is AD converted by the AD converter 11, from the outside of the semiconductor device 1, respectively. The pins INP2, INN2 are supplied with one and the other of the analog differential input signal IN2, which is AD converted by the AD converter 12, from the outside of the semiconductor device 1, respectively.

At the pin OUT1, a digital output signal (hereinafter referred to as output signal OUT1), which is the AD conversion result by the AD converter 11, is output to the outside of the semiconductor device 1. At the pin OUT2, a digital output signal (hereinafter referred to as output signal OUT2), which is the AD conversion result by the AD converter 12, is output to the outside of the semiconductor device 1.

The AD converter 11 is a charge redistribution type successive approximation AD converter, and outputs the analog differential input signal IN1 as a digital output signal OUT1 based on the difference of the reference voltages VREFH, VREFL using a binary search algorithm. Since the AD converter 11 is configured to perform AD conversion based on the difference of the reference voltages VREFH, VREFL for the differential input signal IN1, it can improve the power supply voltage AVCC, AVSS fluctuation removal ratio. Also, the AD converter 11 is configured to further include a redundant comparison operation in the successive comparison operation.

Among the plurality of terminals provided in the AD converter 11, the terminal VH1 is supplied with the reference voltage VREFH. The terminal VH2 is supplied with the power supply voltage AVCC. The terminal VL1 is supplied with the reference voltage VREFL. The terminal VL2 is supplied with the power supply voltage AVSS. The power supply voltages AVCC. AVSS are used to drive the AD converter 11, and the reference voltages VREFH, VREFL are used as the basis for the successive comparison operation of the AD converter 11.

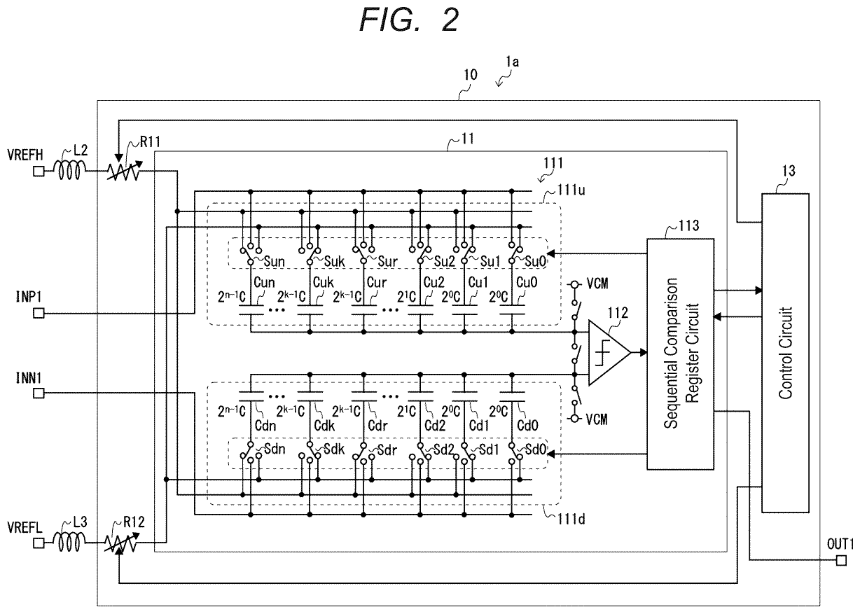

FIG. 2 is a diagram showing an exemplary configuration example of the AD converter 11. The AD converter 11 includes a DA converter 111, a comparator 112, and a sequential comparison register circuit 113. The DA converter 111 is composed of a DA converter 111u provided on the INP1 side of one input signal of the differential input signal IN1, and a DA converter 111d provided on the INN1 side of the other input signal of the differential input signal IN1. The DA converter 111u comprises: capacitance elements Cu0, Cu1 indicating a minimum capacitance value of 2^0·C; n−1 (where n is an integer of 2 or more) capacitance elements Cu2 to Cun, which are binary-weighted relative to the capacitance value of the capacitance element Cu1; a redundant capacitance element Cur indicating the same capacitance value 2^(k−1)·C as the capacitance element Cuk (where k is any of 1 to n); and switches Su0, Su1 to Sun, Sur provided corresponding to each of the capacitance elements Cu0, Cu1 to Cun, Cur. The DA converter 111d comprises: capacitance elements Cd0, Cd1 indicating a minimum capacitance value of 2^0·C; n−1 (where n is an integer of 2 or more) capacitance elements Cd2 to Cdn, which are binary-weighted relative to the capacitance value of the capacitance element Cd1; a redundant capacitance element Cdr indicating the same capacitance value 2^(k−1)·C as the capacitance element Cdk (where k is any of 1 to n); and switches Sd0, Sd1 to Sdn, Sdr provided corresponding to each of the capacitance elements Cd0, Cd1 to Cdn, Cdr. The DA converter 111 also has a function to sample and hold the potential of the input signal IN1.

The AD converter 11 performs a sequential comparison operation of the output of the DA converter 111 and the potential of the input signal IN1, using the comparator 112 and the sequential comparison register circuit 113, while switching the connection of the multiple capacitance elements by the multiple switches and redistributing the charges accumulated in each of the multiple capacitance elements based on the potential of the input signal IN1 and the reference voltages VREFH, VREFL in the DA converter 111.

The variable impedance circuit Z11 is provided on a signal line branching from a signal line common to the AD converter 12, between the pin VREFH and the terminal VH1 of the AD converter 11. For example, the variable impedance circuit Z11 comprises m (where m is an integer of 2 or more) signal lines Z11_1 to Z11_m with different impedances, and a switch SW11 that selects any of the m signal lines Z11_1 to Z11_m based on a control signal from the control circuit 13.

The variable impedance circuit Z12 is provided on a signal line branching from a signal line common to the AD converter 12, between the pin VREFL and the terminal VL1 of the AD converter 11. For example, the variable impedance circuit Z12 comprises m (where m is an integer of 2 or more) signal lines Z12_1 to Z12_m with different impedances, and a switch SW12 that selects any of the m signal lines Z12_1 to Z12_m based on a control signal from the control circuit 13.

The control circuit 13 controls the operation of the AD converter 11 and the impedance of each of the variable impedance circuits Z11, Z12.

The AD converter 12 is a charge redistribution type sequential comparison type AD converter that uses a binary search algorithm to convert an analog differential input signal IN2 into a digital output signal OUT2 based on the difference of the reference voltages VREFH. VREFL. The AD converter 12 is configured to perform AD conversion based on the difference of the reference voltages VREFH, VREFL for the differential input signal IN2, thereby improving the power supply voltage AVCC, AVSS rejection ratio. Furthermore, the AD converter 12 is configured to further include a redundant comparison operation in the sequential comparison operation.

Among the multiple terminals provided in the AD converter 12, the terminal VH1 is supplied with the reference voltage VREFH. The terminal VH2 is supplied with the power supply voltage AVCC. The terminal VL1 is supplied with the reference voltage VREFL. The terminal VL2 is supplied with the power supply voltage AVSS. The power supply voltages AVCC, AVSS are used to drive the AD converter 12, and the reference voltages VREFH, VREFL are used as the basis for the sequential comparison operation of the AD converter 12.

The configuration of the AD converter 12 is the same as that of the AD converter 11, so the explanation is omitted.

The variable impedance circuit Z21 is provided on a signal line branching from a signal line common to the AD converter 11, between the pin VREFH and the terminal VH1 of the AD converter 12. For example, the variable impedance circuit Z21 comprises m (where m is an integer of 2 or more) signal lines Z21_1 to 221_m with different impedances, and a switch SW21 that selects any of the m signal lines Z21_1 to Z21_m based on a control signal from the control circuit 14.

The variable impedance circuit Z22 is provided on a signal line that branches from a signal line common to the AD converter 11, among the signal lines between the pin VREFL and the terminal VL1 of the AD converter 12. For example, the variable impedance circuit Z22 includes m signal lines Z22_1 to Z22_m with different impedances, and a switch SW22 that selects any of the m signal lines Z22_1 to Z22_m based on a control signal from the control circuit 14.

The control circuit 14 controls the operation of the AD converter 12 and the impedance of each of the variable impedance circuits Z21 and Z22.

(Example of Semiconductor Device 1)

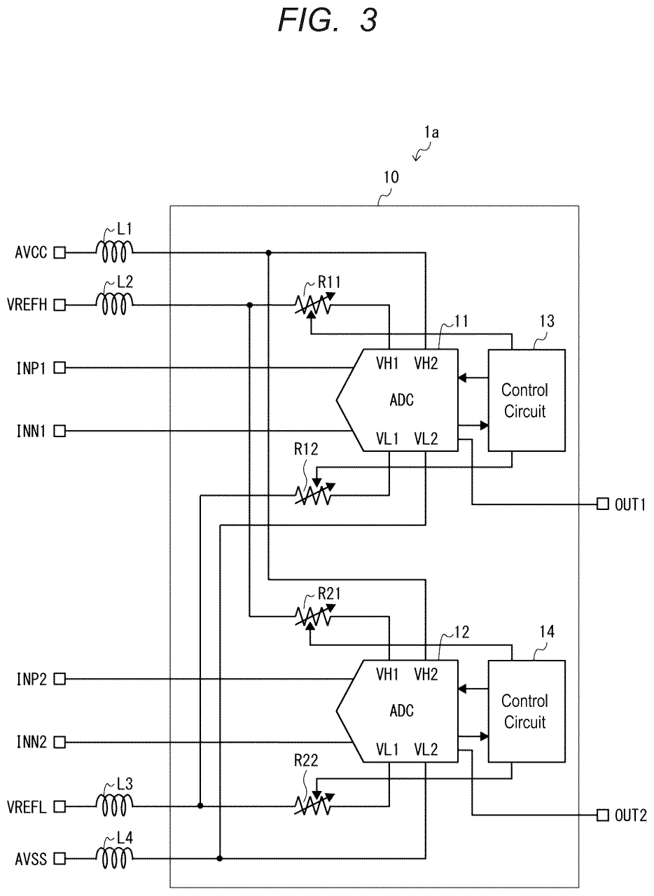

FIG. 3 is a diagram showing an example of the semiconductor device 1 as the semiconductor device 1a. As shown in FIG. 3, the semiconductor device la includes variable resistance circuits R11, R12, R21, and R22 as examples of the variable impedance circuits Z11, Z12, Z21, and Z22, compared to the semiconductor device 1.

The variable resistance circuit R11 is configured to be able to change the resistance value of a signal line that branches from a signal line common to the AD converter 12, among the signal lines between the pin VREFH and the terminal VH1 of the AD converter 11, according to a control signal from the control circuit 13. The variable resistance circuit R12 is configured to be able to change the resistance value of a signal line that branches from a signal line common to the AD converter 12, among the signal lines between the pin VREFL and the terminal VL1 of the AD converter 11, according to a control signal from the control circuit 13. The variable resistance circuit R21 is configured to be able to change the resistance value of a signal line that branches from a signal line common to the AD converter 11, among the signal lines between the pin VREFH and the terminal VH1 of the AD converter 12, according to a control signal from the control circuit 14. The variable resistance circuit R22 is configured to be able to change the resistance value of a signal line that branches from a signal line common to the AD converter 11, among the signal lines between the pin VREFL and the terminal VL1 of the AD converter 12, according to a control signal from the control circuit 14.

The other configurations of the semiconductor device la are the same as those of the semiconductor device 1, so their descriptions are omitted.

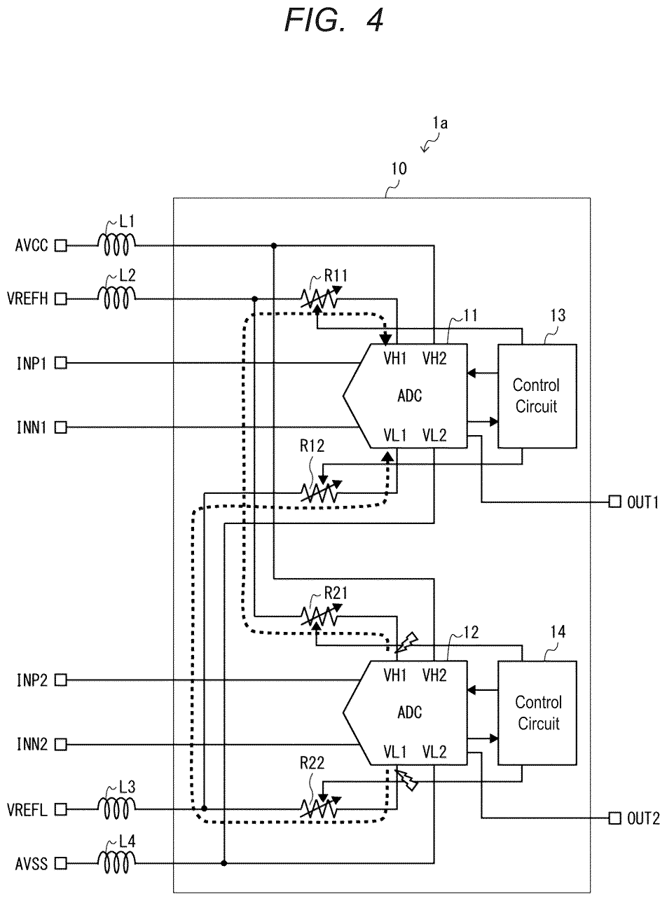

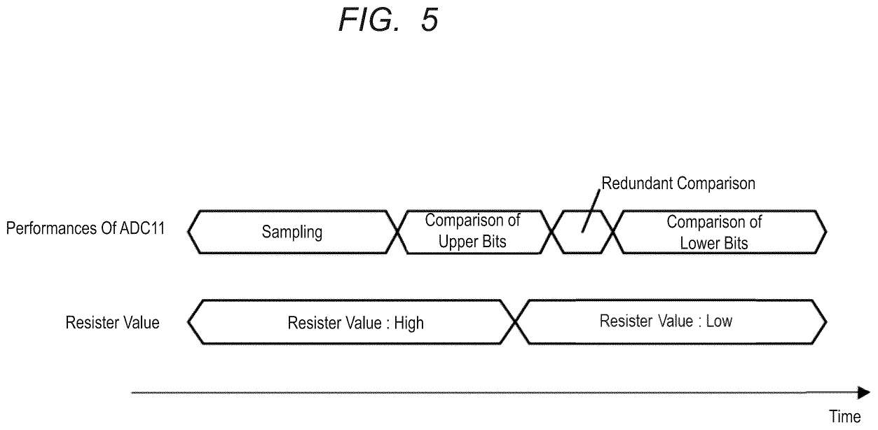

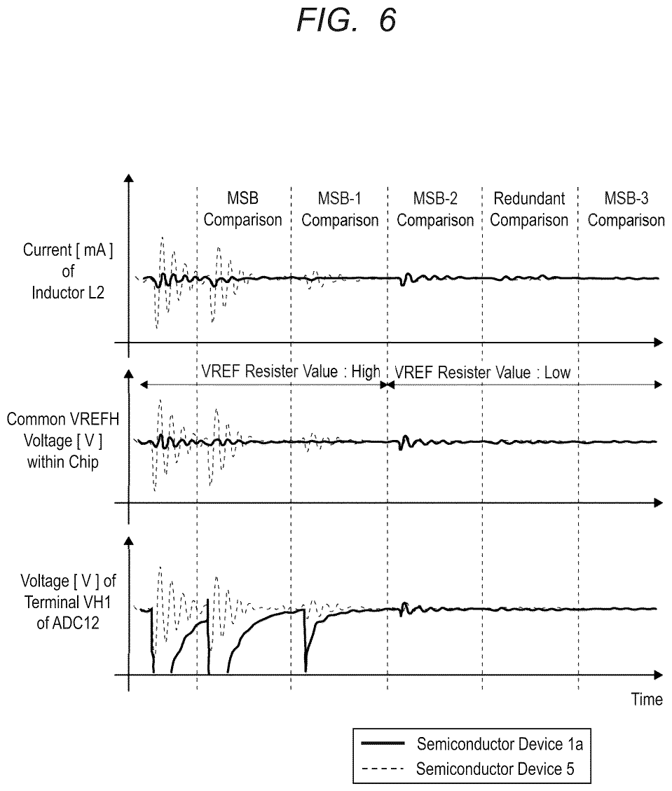

FIG. 4 is a diagram for explaining the propagation path of interference noise generated in the semiconductor device 1a. FIG. 5 is a timing chart showing the operation of the semiconductor device 1a. FIG. 6 is a waveform diagram for explaining the noise generated in the semiconductor device 1a.

In general, it is known that the impedance of inductors such as parasitic inductors LI to L4 greatly changes due to abrupt changes in current.

Here, for example, suppose that in the AD converter 12, the capacity switching of the successive comparison operation is performed asynchronously with the AD converter 11. At this time, at the terminals VH1 and VL1 of the AD converter 12 (terminals where the reference voltages VREFH and VREFL are supplied), the current changes due to the charge and discharge of the charge due to the capacity switching. In particular, in the comparison operation for determining the value of the upper bits of the digital output signal OUT2, the change in current due to the charge and discharge of the charge becomes abrupt because a large capacity switching is performed. When this abrupt change in current at the terminals VH1 and VL1 of the AD converter 12 is transmitted to the parasitic inductors L2 and L3, the impedance of the parasitic inductors L2 and L3 greatly changes. As a result, the reference voltages VREFH and VREFL supplied to the terminals VH1 and VL1 of the AD converter 11 also greatly change. In other words, the noise generated at the terminals VH1 and VL1 of the aggressor AD converter 12 is transmitted to the terminals VH1 and VL1 of the victim AD converter 11. As a result, the AD converter 11 cannot operate accurately.

Therefore, in the semiconductor device 1a, in the comparison operation for determining the value of the upper bits of the output signal OUT2, where the change in current due to the capacity switching is abrupt and the interference noise is likely to become large, the resistance values of the variable resistance circuits R21 and R22 are increased. Accordingly, the changes in the current flowing through each of the parasitic inductors L2, L3 are suppressed, resulting in smaller changes in the impedance of each of the parasitic inductors L2, L3 (see FIG. 6). Accordingly, the fluctuations in the reference voltages VREFH, VREFL supplied to each of the terminals VH1, VL1 of the AD converter 11 are suppressed (see FIG. 6). In other words, the propagation of noise generated at each of the terminals VH1, VL1 of the AD converter 12, which is the aggressor, to the terminals VH1, VL1 of the AD converter 11, which is the victim, is suppressed.

However, because the resistance values of each of the variable resistance circuits R21, R22 are large, the reference voltages VREFH, VREFL supplied to each of the terminals VH1, VL1 of the AD converter 12, which is the aggressor, fluctuate greatly due to IR drop (see FIG. 6). As a result, the AD converter 12 may make a comparison error in the comparison operation for determining the value of the upper bits of the output signal OUT2.

Therefore, in the semiconductor device 1a, in the comparison operation for determining the value of the lower bits (the remaining bits other than the upper bits within a certain range) of the output signal OUT2, which has a small change in current due to the switching of capacitance and small interference noise, and in the redundant comparison operation for re-determining any of the multiple bits representing the output signal OUT2, the resistance values of each of the variable resistance circuits R21, R22 are set lower than in the comparison operation for determining the value of the upper bits. In the redundant comparison operation, the comparison is made with a resolution equal to or greater than that of the comparison operation for determining the value of the lowest bit among the comparison operations for determining the value of the upper bits within a certain range including the highest bit (with a weight of binary search equal to or less than that). In other words, in the redundant comparison operation, the comparison is made with a resolution equal to or greater than that of the comparison operation performed in a state where the resistance values of each of the variable resistance circuits R21, R22 are set high (with a weight of binary search equal to or less than that).

As a result, the IR drop caused by the variable resistance circuits R21, R22 is suppressed, and the fluctuations in the reference voltages VREFH, VREFL supplied to each of the terminals VH1, VL1 of the AD converter 12, which is the aggressor, are suppressed (see FIG. 6). As a result, the AD converter 12 can accurately perform the comparison operation for determining the value of the lower bits and the redundant comparison operation.

In the present embodiment, although the case where the AD converter 12 is the aggressor and the AD converter 11 is the victim is described as an example, the case where the AD converter 11 is the aggressor and the AD converter 12 is the victim is the same.

That is, the semiconductor device la, in the comparison operation for determining the value of the upper bits of the output signal OUT1, which has a rapid change in current due to the switching of capacitance and is prone to generate interference noise, increases the resistance values of each of the variable resistance circuits R11, R12 to suppress the interference noise. Also, the semiconductor device 1a, in the comparison operation for determining the value of the lower bits of the output signal OUT1, which has a slow change in current due to the switching of capacitance and is less likely to generate interference noise, and in the redundant comparison operation, lowers the resistance values of each of the variable resistance circuits R11, R12 than in the comparison operation for determining the value of the upper bits to suppress the IR drop.

As a result, in the semiconductor device 1a, each of the AD converters 11, 12 can operate accurately while suppressing the propagation of interference noise. The control circuits 13, 14 can change the resistance values set by each of the variable resistance circuits R11, R12, R21, R22 as appropriate according to the operating environment, etc.

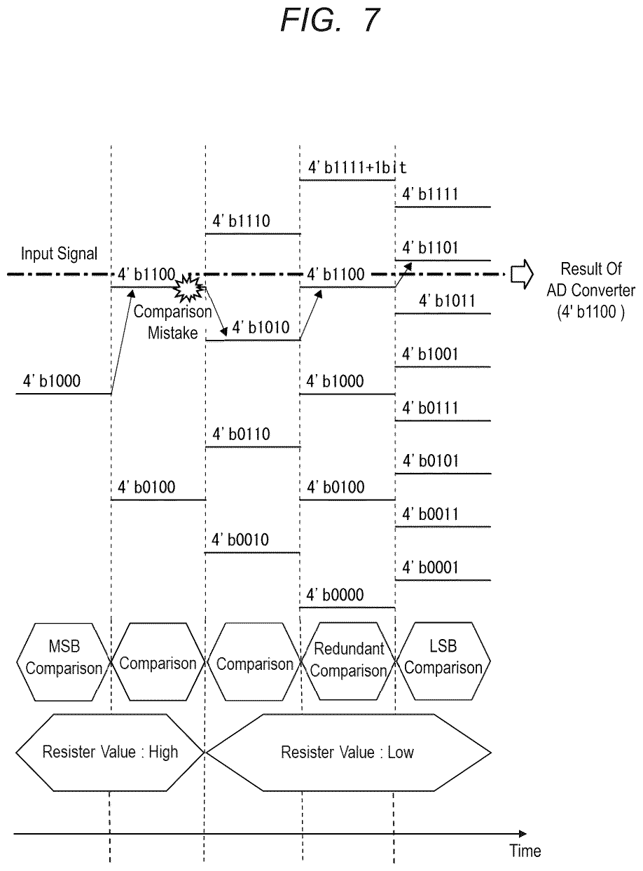

FIG. 7 is a diagram for explaining the successive comparison operation of the AD converter provided in the semiconductor device 1a. In the example of FIG. 7, the AD converter 12 converts the analog input signal IN2 into a 4-bit wide digital output signal OUT2 and outputs it.

First, the AD converter 12 samples the input signal IN2 and holds the sampled input signal IN2.

Next, the AD converter 12 performs a sequential comparison operation for the input signal IN2, while redistributing the charges stored in each of the multiple capacitive elements based on the potential of the input signal IN2 and the reference voltages VREFH, VREFL (hereinafter collectively referred to as reference voltage VREF), by switching the connections of the multiple capacitive elements using multiple switches.

In the initial state, the change in current due to the switching of the capacitance is steep, and interference noise is likely to occur, so the variable resistance circuits R11, R12, R21, R22 are set to high resistance values. This suppresses the interference noise.

First, the AD converter 12 performs a comparison operation to determine the value of the most significant bit (MSB) of the 4 bits representing the output signal OUT2. For example, the AD converter 12 compares the potential of the sampled input signal IN2 with the DA conversion value of the digital value 4b′1000 set with the most significant bit as “1”. If the potential of the input signal IN2 is equal to or greater than the DA conversion value of the digital value 4b′1000, the most significant bit of the output signal OUT2 is confirmed as “1”, and if the potential of the input signal IN2 is less than the DA conversion value of the digital value 4b′1000, the most significant bit of the output signal OUT2 is confirmed as “0”. In the example of FIG. 7, since the potential of the input signal IN2 is equal to or greater than the DA conversion value of the digital value 4b′1000, the most significant bit of the output signal OUT2 is confirmed as “1”.

Subsequently, the AD converter 12 performs a comparison operation to determine the value of the second highest bit of the output signal OUT2 by switching the connection of the capacitive elements by the switch and redistributing the charge. For example, the AD converter 12 compares the potential of the sampled input signal IN2 with the DA conversion value of the digital value 4b′1100 set with the second highest bit as “1”. If the potential of the input signal IN2 is equal to or greater than the DA conversion value of the digital value 4b′1100, the second highest bit of the output signal OUT2 is confirmed as “1”, and if the potential of the input signal IN2 is less than the DA conversion value of the digital value 4b′1100, the second highest bit of the output signal OUT2 is confirmed as “0”.

However, because the resistance values of the variable resistance circuits R21, R22 are high, the reference voltages VREFH, VREFL supplied to the AD converter 12 fluctuate greatly due to the IR drop. As a result, the AD converter 12 may make a comparison error due to the setting error. In the example of FIG. 7, despite the potential of the input signal IN2 being equal to or greater than the DA conversion value of the digital value 4b′1100, the potential of the input signal IN2 is judged to be less than the DA conversion value of the digital value 4b′1100. Therefore, the second highest bit of the output signal OUT2 is erroneously confirmed as “0”.

Subsequently, when the change in current due to the switching of the capacitance becomes gentle and the state where interference noise is less likely to occur, the variable resistance circuits R21, R22 switch to a low resistance value. As a result, the IR drop due to the variable resistance circuits R21, R22 is suppressed, and the fluctuation of the reference voltages VREFH, VREFL supplied to the AD converter 12 is suppressed. Therefore, the AD converter 12 can accurately perform the comparison operation to determine the value of the lower bits and the redundant comparison operation.

Subsequently, the AD converter 12 performs a comparison operation to determine the value of the third highest bit of the output signal OUT2 by switching the connection of the capacitive elements by the switch and redistributing the charge. For example, the AD converter 12 compares the potential of the sampled input signal IN2 with the DA conversion value of the digital value 4b′1010 set with the third highest bit as “1”.

Subsequently, the AD converter 12 performs a redundant comparison operation with the same resolution (at least the same or higher resolution as the comparison operation to determine the value of the second highest bit (the same or lower weight of binary search)) by switching the connection of the capacitive elements by the switch and redistributing the charge. For example, the AD converter 12, in the comparison operation for determining the value of the third highest bit, if the potential of the input signal IN2 is determined to be equal to or greater than the DA conversion value of the digital value to be compared, in the next redundant comparison operation, compares the potential of the input signal IN2 with the DA conversion value of the digital value obtained by adding 4′b0010 to the digital value to be compared. Also, the AD converter 12, in the comparison operation for determining the value of the third highest bit, if the potential of the input signal IN2 is determined to be less than the DA conversion value of the digital value to be compared, in the next redundant comparison operation, compares the potential of the input signal IN2 with the DA conversion value of the digital value obtained by subtracting 4′b0010 from the digital value to be compared.

In the example of FIG. 7, the AD converter 12, in the comparison operation for determining the value of the third highest bit of the output signal OUT2, because the potential of the input signal IN2 is determined to be equal to or greater than the DA conversion value of the digital value 4′b1010, in the next redundant comparison operation, compares the potential of the input signal IN2 with the digital value 4′b1100 obtained by adding 4′b0010 to the digital value 4′b1010.

Then, in the example of FIG. 7, the potential of the input signal IN2 is determined to be equal to or greater than the DA conversion value of the digital value 4′b1100. Therefore, the AD converter 62, in the comparison operation for determining the value of the next least significant bit, compares the potential of the input signal IN2 with the digital value 4′b1101 obtained by adding 4′b0001 to the digital value 4′b1100. For example, if the potential of the input signal IN2 is equal to or greater than the DA conversion value of the digital value 4b′1101, the least significant bit of the output signal OUT2 is determined to be “1”, and if the potential of the input signal IN2 is less than the DA conversion value of the digital value 4b′1101, the least significant bit of the output signal OUT2 is determined to be “0”. In the example of FIG. 7, because the potential of the input signal IN2 is less than the DA conversion value of the digital value 4b′1101, the least significant bit of the output signal OUT2 is determined to be “0”.

As a result, the AD converter 12 converts the analog input signal IN2 into a digital signal and outputs the output signal OUT2 with the digital value 4b′1100.

In this way, the semiconductor device 1a, in the comparison operation for determining the value of the higher bits of the output signal OUT1, where the change in current due to the switching of the capacitance is steep and interference noise is likely to occur, increases the resistance values of each of the variable resistance circuits R11, R12 to suppress the interference noise. Also, the semiconductor device 1a, in the comparison operation for determining the value of the lower bits of the output signal OUT1, and in the redundant comparison operation, where the change in current due to the switching of the capacitance is gentle and interference noise is less likely to occur, lowers the resistance values of each of the variable resistance circuits R11, R12 compared to the comparison operation for determining the value of the higher bits, in order to suppress the IR drop.

Also, the semiconductor device la, in the comparison operation for determining the value of the higher bits of the output signal OUT2, where the change in current due to the switching of the capacitance is steep and interference noise is likely to occur, increases the resistance values of each of the variable resistance circuits R21, R22 to suppress the interference noise. Also, the semiconductor device la, in the comparison operation for determining the value of the lower bits of the output signal OUT2, and in the redundant comparison operation, where the change in current due to the switching of the capacitance is gentle and interference noise is less likely to occur, lowers the resistance values of each of the variable resistance circuits R21, R22 compared to the comparison operation for determining the value of the higher bits, in order to suppress the IR drop.

By doing so, in the semiconductor device 1a, each of the AD converters 11, 12 can operate accurately while suppressing the propagation of interference noise.

### <Second Embodiment>

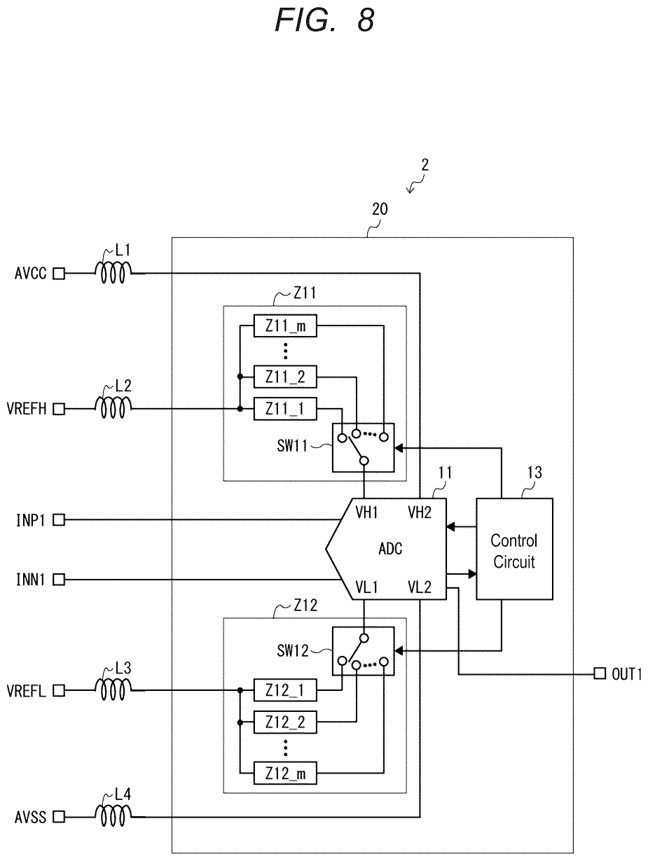

FIG. 8 is a block diagram showing a configuration example of a semiconductor device 2 according to the second embodiment. While the semiconductor device 1 is equipped with two AD converters 11, 12, the semiconductor device 2 is equipped with one AD converter 11.

For example, the semiconductor device 2 is equipped on the chip 20 with the AD converter 11, the control circuit 13, and the variable impedance circuits Z11, Z12. Furthermore, the semiconductor device 2 is at least provided with pins AVCC, AVSS, VREFH, VREFL, INP1, INP2, OUT1, which serve as an interface between the chip 20 and the exterior of the semiconductor device 2.

The configuration of the AD converter 11, control circuit 13, and variable impedance circuits Z11, 212 are the same as in the case of the semiconductor device 1, so their description is omitted. Also, the connection relationship between the AD converter 11, control circuit 13, variable impedance circuits Z11, Z12, and each pin is the same as in the case of the semiconductor device 1, so their description is omitted.

Here, a parasitic inductor L1 is formed on the signal line connected to the pin AVCC by a board substrate, lead frame, bonding wire, etc. (all not shown). Similarly, a parasitic inductor L2 is formed on the signal line connected to the pin VREFH. A parasitic inductor L3 is formed on the signal line connected to the pin VREFL. A parasitic inductor L4 is formed on the signal line connected to the pin AVSS.

### (Exemplary Example of Semiconductor Device 2)

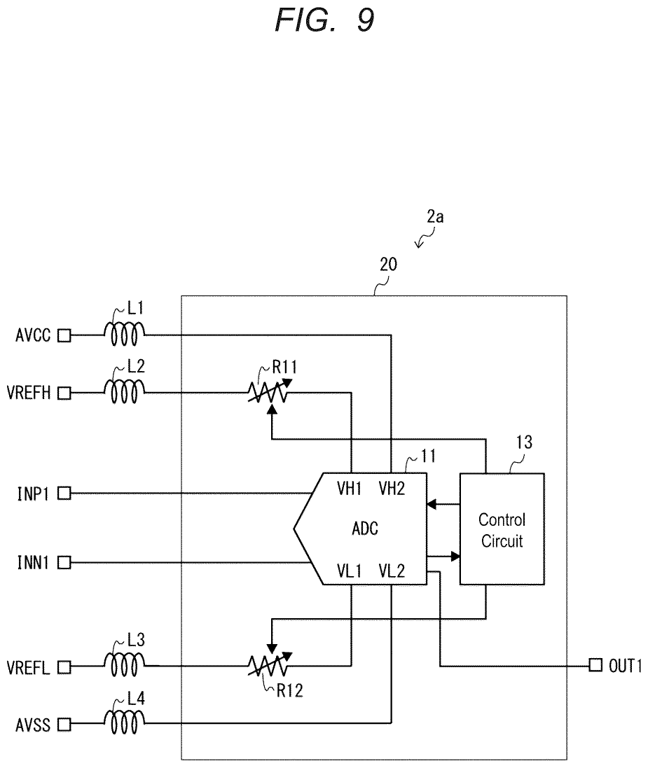

FIG. 9 is a diagram showing an exemplary example of the semiconductor device 2 as the semiconductor device 2a. As shown in FIG. 9, the semiconductor device 2a includes variable resistance circuits R11, R12 as exemplary examples of the variable impedance circuits Z11, 712 compared to the semiconductor device 2. The other configurations of the semiconductor device 2a are the same as in the case of the semiconductor device 2, so their description is omitted.

For example, suppose that a capacity switching operation of the sequential comparison operation is performed in the AD converter 11. At this time, at the terminals VH1, VL1 of the AD converter 11, the current changes due to the charge and discharge caused by the capacity switching. In particular, in the comparison operation for determining the value of the upper bit of the digital output signal OUT1, a large capacity switching is performed, so the current change due to the charge and discharge becomes steep. When this steep current change at the terminals VH1, VL1 of the AD converter 11 is transmitted to the parasitic inductors L2, L3, the impedance of the parasitic inductors L2, L3 changes greatly. As a result, the noise generated on the signal line where the reference voltages VREFH, VREFL propagate becomes large. As a result, noise is transmitted to other circuits (not shown) that share the signal line where the reference voltages VREFH, VREFL propagate, and these other circuits cannot operate accurately.

Therefore, in the semiconductor device 2a, in the comparison operation for determining the value of the upper bit of the output signal OUT1, where the current change due to the capacity switching is steep and interference noise is likely to occur, the resistance values of each of the variable resistance circuits R11, R12 are increased to suppress the interference noise. Also, the semiconductor device 2a, in the comparison operation for determining the value of the lower bit of the output signal OUT1, where the current change due to the capacity switching is gentle and interference noise is less likely to occur, and in the redundant comparison operation, the resistance values of each of the variable resistance circuits R11, R12 are lower than in the comparison operation for determining the value of the upper bit to suppress the IR drop. As a result, in the semiconductor device 2a, the AD converter 11 can operate accurately while suppressing the propagation of interference noise.

### <Third Embodiment>

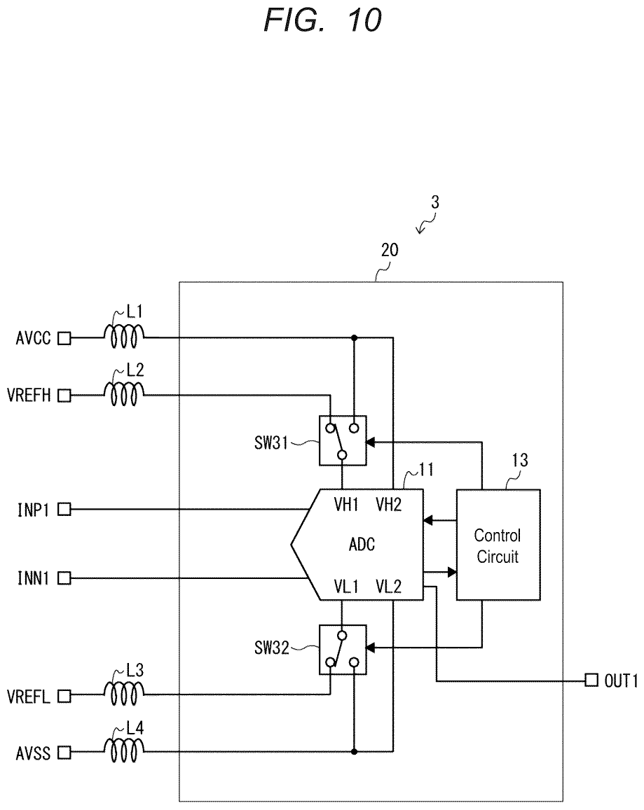

FIG. 10 is a block diagram showing a configuration example of a semiconductor device 3 according to the third embodiment. The semiconductor device 3 includes switches SW31, SW32 instead of the variable impedance circuits Z11, 712 compared to the semiconductor device 2.

The switch SW31 is provided between the pin VREFH and pin AVCC and the terminal VH1 of the AD converter 11, and connects either the pin VREFH or pin AVCC to the terminal VH1 of the AD converter 11 according to a control signal from the control circuit 13. The switch SW32 is provided between the pin VREFL and pin AVSS and the terminal VL1 of the AD converter 11, and connects either the pin VREFL or pin AVSS to the terminal VL1 of the AD converter 11 according to a control signal from the control circuit 13.

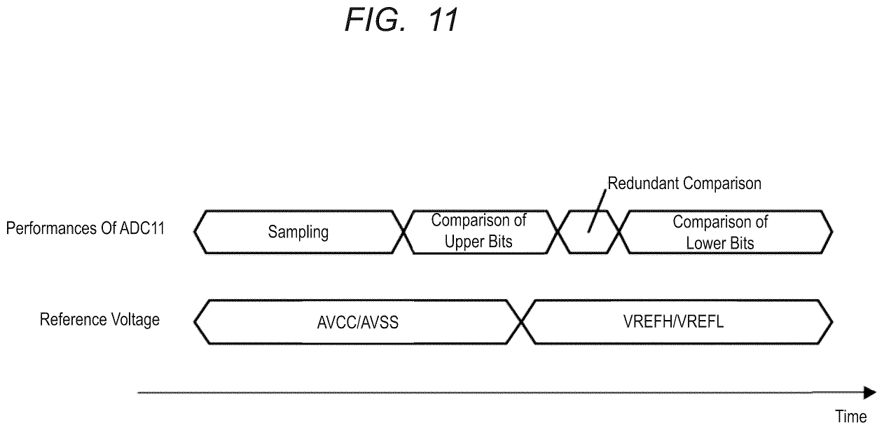

FIG. 11 is a timing chart showing the operation of the semiconductor device 3. Firstly, the semiconductor device 3, in the comparison operation for determining the value of the higher bits of the output signal OUT1, where the current change associated with the capacity switching is steep and interference noise is likely to occur, connects the pins AVCC, AVSS and the terminals VH1, VL1 of the AD converter 11 by the switches SW31, SW32. Here, since the AD converter 11 is configured to perform AD conversion based on the difference of the reference voltages VREFH, VREFL for the differential input signal IN1, the power supply voltage AVCC, AVSS has a high fluctuation removal ratio. Therefore, the propagation of noise (i.e., interference noise) generated at VH1, VL1 of the AD converter 11 is suppressed.

Also, the semiconductor device 3, in the comparison operation for determining the value of the lower bits of the output signal OUT1, where the current change associated with the capacity switching is gentle and interference noise is less likely to occur, and in the redundant comparison operation, connects the pins VREFH, VREFL and the terminals VH1, VL1 of the AD converter 11 by the switches SW31, SW32. As a result, in the semiconductor device 3, the AD converter 11 can operate accurately while suppressing the propagation of interference noise.

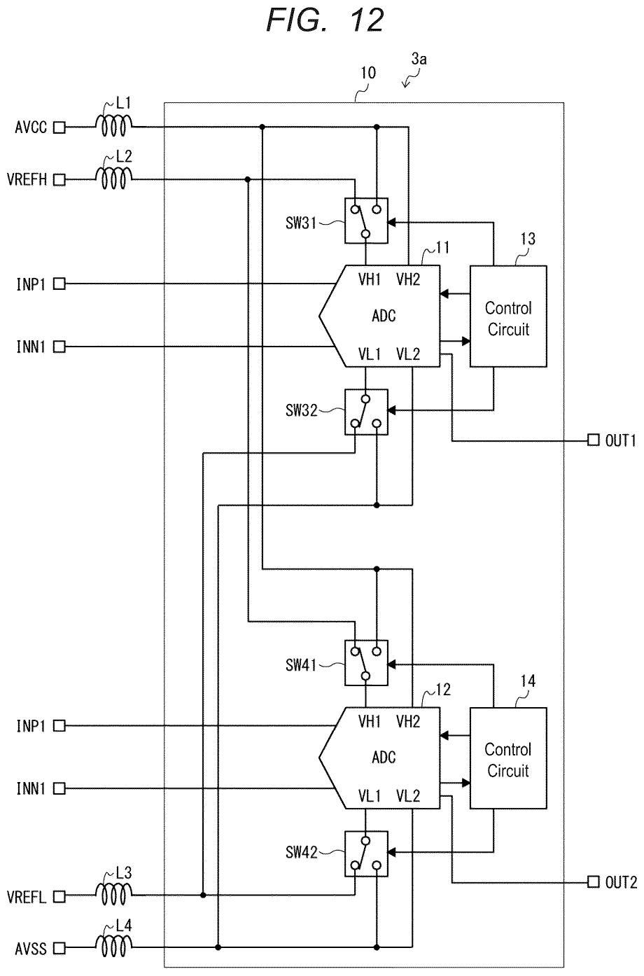

Similarly, the semiconductor device 1 may be provided with the switches SW31. SW32 instead of the variable impedance circuits Z11, Z12, and with the switches SW41, SW42 instead of the variable impedance circuits Z21, Z22. FIG. 12 is a block diagram showing a configuration example of the semiconductor device 3a. The semiconductor device 3a is provided with the switches SW31, SW32 instead of the variable impedance circuits Z11, Z12, and with the switches SW41, SW42 instead of the variable impedance circuits Z21, Z22.

The switch SW41 is provided between the pins VREFH and AVCC and the terminal VH1 of the AD converter 12, and selects either of the pins VREFH and AVCC according to the control signal from the control circuit 14, and connects it to the terminal VH1 of the AD converter 12. The switch SW42 is provided between the pins VREFL and AVSS and the terminal VL1 of the AD converter 12, and selects either of the pins VREFL and AVSS according to the control signal from the control circuit 14, and connects it to the terminal VL1 of the AD converter 12.

Although certain aspects of the invention made by the inventor have been specifically described based on the embodiment, the present invention is not limited to the embodiment already described, and it is needless to say that various modifications can be made without departing from the gist thereof.

Furthermore, this disclosure can realize some or all of the processing of the semiconductor devices 1 to 3 by executing a computer program on a CPU (Central Processing Unit).

The program described above, when loaded into a computer, includes a group of instructions (or software code) for causing the computer to perform one or more functions described in the embodiment. The program may be stored in a non-transitory computer-readable medium or a tangible memory medium. Non-limiting examples of the computer-readable medium or tangible memory medium include RAM (Random-Access Memory), ROM (Read-Only Memory), flash memory, SSD (Solid-State Drive) or other memory technologies, CD-ROM, DVD (Digital Versatile Disc), Blu-ray (registered trademark) disc or other optical disc storage, magnetic cassette, magnetic tape, magnetic disk storage or other magnetic storage devices. The program may be transmitted on a temporary computer-readable medium or communication medium. Non-limiting examples of the temporary computer-readable medium or communication medium include electrical, optical, acoustic, or other forms of propagation signals.

What is claimed is:

1. A semiconductor device comprising:
a first AD converter of a charge redistribution type that includes a redundant comparison operation in a sequential comparison operation and outputs a first output signal in digital form by converting a first input signal of an analog differential using a reference voltage; and
a first variable impedance circuit that is provided on a signal line between a first pin to which the reference voltage is supplied from outside and the first AD converter, and is configured to be able to change impedance,
a first control circuit that controls the impedance of the first variable impedance circuit according to the operating condition of the first AD converter.

2. The semiconductor device according to claim 1.
wherein the first control circuit controls the impedance of the first variable impedance circuit to a first impedance when the first AD converter performs a comparison operation to determine the value of the upper bits in a first predetermined range of multiple bits representing the first output signal, and
wherein the first control circuit controls the impedance of the first variable impedance circuit to a second impedance lower than the first impedance when the first AD converter performs a comparison operation to determine the value of the lower bits other than the upper bits in the first predetermined range of the multiple bits representing the first output signal and performs a first redundant comparison operation.

3. The semiconductor device according to claim 2,
wherein the first AD converter is configured to perform the first redundant comparison operation with a resolution equal to or higher than that of the comparison operation to determine the value of the least significant bit among the upper bits in the first predetermined range.

4. The semiconductor device according to claim 1,
wherein the first AD converter has a first DA converter having multiple first capacitive elements and multiple first switches, a first comparator, and a first sequential comparison register circuit, and
wherein the first DA converter is configured to perform a sequential comparison of the potential of the first input signal and the output of the first DA converter, using the first comparator and the first sequential comparison register circuit, while redistributing the charge stored in the multiple first capacitive elements by switching the connections of the multiple first capacitive elements with the multiple first switches, based on the potential of the first input signal and the reference voltage.

5. The semiconductor device according to claim 1, wherein the first variable impedance circuit is a first variable resistance circuit configured to be able to change resistance.

6. The semiconductor device according to claim 1,
wherein the first AD converter is driven by a power supply voltage, and
wherein the first variable impedance circuit is a first selection circuit that selects either the first pin or a second pin to which the power supply voltage is supplied from outside according to the operating condition of the first AD converter and supplies the reference voltage to the first AD converter.

7. The semiconductor device according to claim 6, wherein the first variable impedance circuit is configured to be able to select any of the formation paths of multiple parasitic inductors.

8. The semiconductor device according to claim 1, further comprising:
a second AD converter of a charge redistribution type that includes a redundant comparison operation in a sequential comparison operation and outputs a second output signal in digital form by converting a second input signal of an analog differential using the reference voltage;
a second variable impedance circuit that is provided on a signal line between the first pin to which the reference voltage is supplied from outside and the second AD converter and is configured to be able to change impedance; and
a second control circuit that controls the impedance of the second variable impedance circuit according to the operating condition of the second AD converter.

9. The semiconductor device according to claim 8,
wherein the first control circuit controls the impedance of the first variable impedance circuit to a first impedance when the first AD converter performs a comparison operation to determine the value of the upper bits within a first predetermined range of the multiple bits representing the first output signal,
wherein the first control circuit controls the impedance of the first variable impedance circuit to a second impedance lower than the first impedance when the first AD converter performs a comparison operation to determine the value of the lower bits other than the upper bits within the first predetermined range of the multiple bits representing the first output signal, and a comparison operation with a first redundancy,
wherein the second control circuit controls the impedance of the second variable impedance circuit to a third impedance when executing a comparison operation to determine the value of the upper bits within a second predetermined range of the multiple bits representing the second output signal by the second AD converter, and
wherein the second control circuit controls the impedance of the second variable impedance circuit to a fourth impedance lower than the third impedance when the second AD converter executes a comparison operation to determine the value of the lower bits other than the upper bits within the second predetermined range of the multiple bits representing the second output signal, and a comparison operation with a second redundancy.

10. The semiconductor device according to claim 9,
wherein the first AD converter is configured to execute the comparison operation with the first redundancy at a resolution equal to or higher than the comparison operation to determine the value of the least significant bit among the upper bits within the first predetermined range, and
wherein the second AD converter is configured to execute the comparison operation with the second redundancy at a resolution equal to or higher than the comparison operation to determine the value of the least significant bit among the upper bits within the second predetermined range.

11. The semiconductor device according to claim 8,
wherein the first AD converter has a first DA converter with multiple first capacitive elements and multiple first switches, a first comparator, and a first sequential comparison register circuit,
wherein the first DA converter is configured to perform a sequential comparison of the potential of the first input signal and the output of the first DA converter, using the first comparator and the first sequential comparison register circuit, while redistributing the charge stored in the plurality of first capacitive elements based on the potential of the first input signal and the reference voltage, by switching the connection of the plurality of first capacitive elements with the plurality of first switches,
wherein the second AD converter has a second DA converter with multiple second capacitive elements and multiple second switches, a second comparator, and a second sequential comparison register circuit, and
wherein the second DA converter is configured to perform a sequential comparison of the potential of the second input signal and the output of the second DA converter, using the second comparator and the second sequential comparison register circuit, while redistributing the charge stored in the plurality of second capacitive elements based on the potential of the second input signal and the reference voltage, by switching the connection of the plurality of second capacitive elements with the plurality of second switches.

12. The semiconductor device according to claim 8,
wherein the first variable impedance circuit is a first variable resistance circuit configured to be able to change the resistance value, and
wherein the second variable impedance circuit is a second variable resistance circuit configured to be able to change the resistance value.

13. The semiconductor device according to claim 8,
wherein the first AD converter is driven by a power supply voltage,
wherein the first variable impedance circuit is a first selection circuit that selects either the first pin or the second pin from which the power supply voltage is supplied from the outside according to the operating condition of the first AD converter and supplies it to the first AD converter as the reference voltage,
wherein the second AD converter is driven by the power supply voltage, and
wherein the second variable impedance circuit is a second selection circuit that selects either the first pin or the second pin from which the power supply voltage is supplied from the outside according to the operating condition of the second AD converter and supplies it to the second AD converter as the reference voltage.

14. The semiconductor device according to claim 13,
wherein the first variable impedance circuit is configured to be able to select any of the formation paths of multiple parasitic inductors, and
wherein the second variable impedance circuit is configured to be able to select any of the formation paths of the multiple parasitic inductors.

15. A control method for a semiconductor device, comprising:
a first AD converter of a charge redistribution type sequential comparison type that includes a redundant comparison operation in a sequential comparison operation and outputs a first output signal in digital form by converting a first input signal of an analog differential using a reference voltage;
a first variable impedance circuit provided on a signal line between a first pin supplied with the reference voltage from the outside and the first AD converter, and configured to change the impedance; and
a first control circuit that controls the impedance of the first variable impedance circuit according to the operating condition of the first AD converter,
wherein the impedance of the first variable impedance circuit is controlled to a first impedance,
wherein the first AD converter performs a comparison operation to determine the value of the upper bits within a first predetermined range of the multiple bits representing the first output signal,
wherein the impedance of the first variable impedance circuit is controlled to a second impedance lower than the first impedance, and
wherein the first AD converter performs a comparison operation to determine the value of the lower bits other than the upper bits within the first predetermined range of the multiple bits representing the first output signal, and performs a redundant comparison operation.

16. A control program for executing control processing in a semiconductor device on a computer, comprising:
a first AD converter of a charge redistribution type sequential comparison type that includes a redundant comparison operation in a sequential comparison operation and outputs a first output signal in digital form by converting a first input signal of an analog differential using a reference voltage;
a first variable impedance circuit provided on a signal line between a first pin supplied with the reference voltage from the outside and the first AD converter, and configured to change the impedance; and
a first control circuit that controls the impedance of the first variable impedance circuit according to the operating condition of the first AD converter,
wherein a process of controlling the impedance of the first variable impedance circuit to a first impedance,
wherein a process of performing a comparison operation in the first AD converter to determine the value of the upper bits in a first predetermined range among the multiple bits representing the first output signal,
wherein a process of controlling the impedance of the first variable impedance circuit to a second impedance lower than the first impedance, and
wherein a process of performing a comparison operation in the first AD converter to determine the value of the lower bits other than the upper bits in the first predetermined range among the multiple bits representing the first output signal, and a redundant comparison operation.
